(19) United States
(12) Patent Application Publication
(10) Pub. No.: US 2023/0352436 A1
(43) Pub. Date: Nov. 2, 2023

(54) ADHESIVE FOR SEMICONDUCTORS, AND SEMICONDUCTOR DEVICE AND METHOD FOR PRODUCING SAME

(71) Applicant: Resonac Corporation, Minato-ku, Tokyo (JP)

(72) Inventors: Toshiyasu AKIYOSHI, Minato-ku, Tokyo (JP); Keiko UENO, Minato-ku, Tokyo (JP)

(21) Appl. No.: 18/043,730

(22) PCT Filed: Sep. 16, 2020
(86) PCT No.: PCT/JP2020/035093

§ 371 Date: Mar. 2, 2023

(51) Int. Cl. H01L 23/00; C09J 11/06; C09J 163/00; H01L 25/065

(52) U.S. Cl. CPC H01L 24/29; C09J 11/06; C09J 163/00; H01L 25/0657; H01L 24/16; H01L 24/32; H01L 24/73; H01L 24/81; H01L 24/83; C09J 2203/326; C09J 2301/312; C09J 2301/50; H01L 2225/06513; H01L 2225/06517; H01L 2224/16148; H01L 2224/16227; H01L 2224/16238; H01L 2224/2919; H01L 2224/32145; H01L 2224/32225; H01L 2224/73204; H01L 2224/81203; H01L 2224/83862; H01L 2924/3511

(57) ABSTRACT

An adhesive for a semiconductor, the adhesive containing a thermoplastic resin, a thermosetting resin, a curing agent, and a flux compound having an acid group, in which an exothermic calorific value at 60 to 155° C. of a DSC curve obtained by differential scanning calorimetry in which the adhesive for a semiconductor is heated at a temperature increase rate of 10° C./min is 20 J/g or less, and a minimum melt viscosity of a viscosity curve obtained by shear viscosity measurement in which the adhesive for a semiconductor is heated at a temperature increase rate of 10° C./min is 2000 Pa·s or more.

### TECHNICAL FIELD

The present disclosure relates to an adhesive for a semiconductor, and a semiconductor device and a method for manufacturing the same.

### BACKGROUND ART

Conventionally, to connect a semiconductor chip to a substrate, a wire bonding method using metal thin lines such as gold wires has been widely used.

In recent years, to meet requirements for higher functions, larger scale integration, higher speed, and the like of semiconductor devices, a flip chip connection method (FC connection method) has been becoming popular, in which a conductive projection called a bump is formed on a semiconductor chip or a substrate to directly connect the semiconductor chip to the substrate.

Examples of connection between the semiconductor chip and the substrate by the FC connection method also include a COB (Chip On Board) connection method frequently used in BGA (Ball Grid Array), CSP (Chip Size Package), and the like. Furthermore, the FC connection method is also widely used in a COC (Chip On Chip) connection method in which connection portions (bumps or wires) are formed on semiconductor chips to connect the semiconductor chips to each other and a COW (Chip On Wafer) connection method in which connection portions (bumps or wires) are formed on semiconductor wafers to connect the semiconductor chips to the semiconductor wafers (see, for example, Patent Literature 1).

Furthermore, packages for which there is great demand for reductions in size and profile as well as higher functions increasingly use chip-stack package including chips laminated and multi-staged by the aforementioned connection method, or POP (Package On Package), TSV (Through-Silicon Via), and the like. Such laminating and multi-staging techniques dispose semiconductor chips and the like three-dimensionally, which can attain a smaller package than that in use of techniques of disposing semiconductor chips two-dimensionally. Furthermore, the laminating and multi-staging techniques are also effective in an improvement in performance of semiconductors, a reduction in noise, a packaging area, and energy consumption, and the like, and receive attention as a semiconductor wiring technique of the next generation.

Incidentally, metal bonding is usually used to connect connection portions from the viewpoint of sufficiently ensuring connection reliability (for example, insulation reliability). Examples of metals mainly used in the above-described connection portions (for example, bumps and wires) include solder, tin, gold, silver, copper, and nickel, and a conductive material containing a plurality of these is also used. The metal used in the connection portion may generate an oxidized film due to oxidation of the surface of the metal, or impurities such as an oxide may adhere to the surface of the metal to generate impurities on a connection surface of the connection portion in some cases. When such impurities remain, there is a concern that connection reliability (for example, insulation reliability) between the semiconductor chip and the substrate or between two semiconductor chips is reduced to impair the merits of adopting the aforementioned connection method.

Furthermore, as a method for suppressing generation of these impurities, there is mentioned a method known as an OSP (Organic Solderbility Preservatives) treatment or the like in which a connection portion is coated with an antioxidizing film; however, this antioxidizing film may cause a reduction in solder wettability during a connection process, a reduction in connectivity, and the like in some cases.

In this regard, as a method for removing the aforementioned oxidized film and impurities, a method for containing a fluxing agent in an adhesive for a semiconductor has been proposed (see, for example, Patent Literature 2).

### CITATION LIST

### Patent Literature

Patent Literature 1: Japanese Unexamined Patent Publication No. 2008-294382
Patent Literature 2: International Publication WO 2013/125086

### SUMMARY OF INVENTION

### Technical Problem

In recent years, from the viewpoint of improving productivity, a process of mounting a plurality of semiconductor chips onto a member to be mounted (such as a semiconductor chip, a semiconductor wafer, or a wiring circuit substrate) through an adhesive for a semiconductor and temporarily fixing the plurality of semiconductor chips, and then performing curing and sealing collectively has been proposed. In this process, by applying heat (about 60 to 155° C.) to the stage to the extent that the adhesive for a semiconductor can flow, the semiconductor chips are temporarily fixed onto the member to be mounted, and high-temperature press-bonded again at a temperature (for example, about 260° C.) equal to or higher than the melting point of the connection portion (bump or wire) to perform metal bonding, and the adhesive for a semiconductor is cured collectively. According to this process, a plurality of packages can be efficiently produced.

In the above-described process, voids may remain in the adhesive for a semiconductor in some cases, and in order to prevent generation of such voids, a method of performing collective curing under a pressurized condition has been proposed. However, when the number of semiconductor chips increases, voids may remain even in the above-described method in some cases, and thus it becomes clear that there is room for further improvement.

Therefore, an object of the present disclosure is to reduce voids that may remain in an adhesive for a semiconductor in a process of temporarily fixing a plurality of semiconductor chips onto a member to be mounted through an adhesive for a semiconductor, high-temperature press-bonding the plurality of semiconductor chips to perform metal bonding, and then performing curing and sealing collectively.

That is, an object of the present disclosure is to provide an adhesive for a semiconductor capable of reducing the above-described voids, and a semiconductor device and a method for manufacturing the same that use the above-described adhesive for a semiconductor.

### Solution to Problem

The present inventors have speculated that lots of voids are generated during high-temperature press-bonding of the process described above, and as a result, the voids are likely to remain in the adhesive for a semiconductor. That is, since high-temperature heat is rapidly applied to the adhesive for a semiconductor during the high-temperature press-bonding described above, it is considered that foaming and expansion of a volatile component contained in the adhesive for a semiconductor increase voids. There is also a step of removing voids by pressurizing during collective curing after such high-temperature press-bonding, but when the amount of voids before curing is too large, it is speculated that the voids are not completely crushed even by pressurizing and some of the voids remain.

Furthermore, in a case where the number of semiconductor chips mounted on the semiconductor wafer is large, the adhesive for a semiconductor is partially cured during temporary fixing and high-temperature press-bonding, and as a result, it is speculated that voids are likely to remain in the adhesive for a semiconductor. That is, in the above-described process, since semiconductor chips are sequentially mounted, thermal history by the stage is continuously applied to the semiconductor chip initially mounted and the adhesive for a semiconductor until the mounting of the final semiconductor chip is completed. Therefore, when the number of semiconductor chips increases, curing of the adhesive for a semiconductor to temporarily fix semiconductor chips initially mounted partially progresses, and it is speculated that voids remain without being removed by pressurizing during collective curing. The present inventors have further conducted studies based on the above speculation and have completed the present invention.

Several aspects of the present disclosure provide the following.
[1] An adhesive for a semiconductor, the adhesive containing a plastic resin, a thermosetting resin, a curing agent, and a flux compound having an acid group, in which an exothermic calorific value at 60 to 155° C. of a DSC curve obtained by differential scanning calorimetry in which the adhesive for a semiconductor is heated at a temperature increase rate of 10° C./min is 20 J/g or less, and a minimum melt viscosity of a viscosity curve obtained by shear viscosity measurement in which the adhesive for a semiconductor is heated at a temperature increase rate of 10° C./min is 2000 Pas or more.
[2] The adhesive for a semiconductor described in the above [1], in which the minimum melt viscosity is 3000 Pas or more.
[3] The adhesive for a semiconductor described in the above [1], in which the minimum melt viscosity is 4000 Pas or more.
[4] The adhesive for a semiconductor described in any one of the above [1] to [3], in which the minimum melt viscosity is 20000 Pas or less.
[5] The adhesive for a semiconductor described in any one of the above [1] to [3], in which the minimum melt viscosity is 15000 Pas or less.
[6] The adhesive for a semiconductor described in any one of the above [1] to [3], in which the minimum melt viscosity is 10000 Pas or less.
[7] The adhesive for a semiconductor described in any one of the above [1] to [6], in which an onset temperature of the DSC curve obtained by differential scanning calorimetry in which the adhesive for a semiconductor is heated at a temperature increase rate of 10° C./min is 155° C. or higher.
[8] The adhesive for a semiconductor described in any one of the above [1] to [7], in which a temperature at which the adhesive for a semiconductor has the minimum melt viscosity is 135° C. or higher.
[9] The adhesive for a semiconductor described in any one of the above [1] to [7], in which a temperature at which the adhesive for a semiconductor has the minimum melt viscosity is 140° C. or higher.
[10] The adhesive for a semiconductor described in any one of the above [1] to [7], in which a temperature at which the adhesive for a semiconductor has the minimum melt viscosity is 145° C. or higher.
[11] The adhesive for a semiconductor described in any one of the above [1] to [10], in which a viscosity at 80° C. of the viscosity curve obtained by shear viscosity measurement in which the adhesive for a semiconductor is heated at a temperature increase rate of 10° C./min is 10000 Pa·s or more.
[12] The adhesive for a semiconductor described in any one of the above [1] to [11], in which a weight average molecular weight of the thermoplastic resin is 10000 or more.
[13] The adhesive for a semiconductor described in any one of the above [1] to [12], in which a content of the thermoplastic resin is 1 to 30% by mass on the basis of the total amount of solid contents of the adhesive for a semiconductor.
[14] The adhesive for a semiconductor described in any one of the above [1] to [13], in which a content of the thermoplastic resin is 5% by mass or more on the basis of the total amount of solid contents of the adhesive for a semiconductor.
[15] The adhesive for a semiconductor described in any one of the above [1] to [14], in which the curing agent includes an amine-based curing agent.
[16] The adhesive for a semiconductor described in any one of the above [1] to [15], in which the curing agent includes an imidazole-based curing agent.
[17] The adhesive for a semiconductor described in any one of the above [1] to [16], in which a content of the curing agent is 2.3% by mass or less on the basis of the total amount of solid contents of the adhesive for a semiconductor.
[18] The adhesive for a semiconductor described in any one of the above [1] to [17], in which a melting point of the flux compound is to 230° C.
[19] The adhesive for a semiconductor described in any one of the above [1] to [18], in which a melting point of the flux compound is 100 to 170° C.
[20] The adhesive for a semiconductor described in any one of the above [1] to [19], in which the thermosetting resin contains an epoxy resin.
[21] The adhesive for a semiconductor described in any one of the above [1] to [20], in which the thermosetting resin does not substantially contain an epoxy resin that is a liquid at 35° C.
[22] The adhesive for a semiconductor described in any one of the above [1] to [21], in which the adhesive for a semiconductor has a film shape.
[23] The adhesive for a semiconductor described in any one of the above [1] to [22], in which the adhesive for a semiconductor is cured by applying heat under a pressurized atmosphere.
[24] A method for manufacturing a semiconductor device in which connection portions of a semiconductor chip and a wiring circuit substrate are electrically connected to each other or a semiconductor device in which connection portions of a plurality of semiconductor chips are electrically connected to each other, the method including: a sealing step of curing the adhesive for a semiconductor described in any one of the above [1] to [23] by applying heat under a pressurized atmosphere to seal at least a part of the connection portion with the cured adhesive for a semiconductor.
[25] The method for manufacturing a semiconductor device described in the above [24], further including, before the sealing step: a step of disposing a plurality of semiconductor chips on a stage; and a temporarily fixing step of sequentially disposing another semiconductor chip on each of the plurality of semiconductor chips disposed on the stage with the adhesive for a semiconductor interposed therebetween while the stage is heated to 60 to 155° C. to obtain a plurality of laminates in which the semiconductor chip, the adhesive for a semiconductor, and the other semiconductor chip are laminated in this order.
[26] The method for manufacturing a semiconductor device described in the above [25], further including, after the temporarily fixing step and before the sealing step: a bonding step of forming metal bonding between the respective connection portions by press-bonding the semiconductor chips and the other semiconductor chips while heating to a temperature equal to or higher than a melting point of at least one connection portion among the respective connection portions.
[27] The method for manufacturing a semiconductor device described in the above [24], further including, before the sealing step: a step of disposing a wiring circuit substrate or a semiconductor wafer on a stage; and a temporarily fixing step of sequentially disposing a plurality of semiconductor chips on the wiring circuit substrate or the semiconductor wafer disposed on the stage with the adhesive for a semiconductor interposed therebetween while the stage is heated to 60 to 155° C. to obtain a laminate in which the wiring circuit substrate, the adhesive for a semiconductor, and the plurality of semiconductor chips are laminated in this order or a laminate in which the semiconductor wafer, the adhesive for a semiconductor, and the plurality of semiconductor chips are laminated in this order.
[28] The method for manufacturing a semiconductor device described in the above [27], further including, after the temporarily fixing step and before the sealing step: a bonding step of forming metal bonding between the respective connection portions by press-bonding the wiring circuit substrate or the semiconductor wafer and the semiconductor chips while heating to a temperature equal to or higher than a melting point of at least one connection portion among the respective connection portions.
[29] A semiconductor device in which connection portions of a semiconductor chip and a wiring circuit substrate are electrically connected to each other or a semiconductor device in which connection portions of a plurality of semiconductor chips are electrically connected to each other, at least a part of the connection portion being sealed with a cured product of the adhesive for a semiconductor described in any one of the above [1] to [23] cured by applying heat under a pressurized atmosphere.

### Advantageous Effects of Invention

According to the present disclosure, voids that may remain in an adhesive for a semiconductor can be reduced in a process of temporarily fixing a plurality of semiconductor chips onto a member to be mounted through an adhesive for a semiconductor, high-temperature press-bonding the plurality of semiconductor chips to perform metal bonding, and then performing curing and sealing collectively. According to the present disclosure, it is possible to provide an adhesive for a semiconductor capable of reducing such voids, and a semiconductor device with such voids reduced and a method for manufacturing the same.

### BRIEF DESCRIPTION OF DRAWINGS

FIG. 1 is a schematic cross-sectional view illustrating an embodiment of a semiconductor device.

FIG. 2 is a schematic cross-sectional view illustrating an embodiment of a semiconductor device.

FIG. 3 is a schematic cross-sectional view illustrating an embodiment of a semiconductor device.

FIG. 4 is a schematic cross-sectional view illustrating an embodiment of a method for manufacturing a semiconductor device.

### DESCRIPTION OF EMBODIMENTS

Hereinafter, an embodiment of the present disclosure will be specifically described with reference to the drawings in some cases. Note that, In the drawings, same reference numerals are given to identical or equivalent portions, and duplication of description will be omitted. Furthermore, unless otherwise specified, positional relationships such as top, bottom, right, and left are assumed to be based on positional relationships illustrated in the drawings. Further, dimensional ratios in the drawings will not be limited to ratios shown in the drawings.

Upper limit values and lower limit values of numerical ranges described in the present specification can be arbitrarily combined. Numerical values described in Examples can also be used as the upper limit values or the lower limit values of the numerical ranges. In the present specification, the term “(meth)acryl” means acryl or methacryl corresponding thereto.

<Adhesive for Semiconductor and Producing Method Therefor>

An adhesive for a semiconductor of the present embodiment contains a thermoplastic resin (hereinafter, referred to as “component (a)” in some cases), a thermosetting resin (hereinafter, referred to as “component (b)” in some cases), a curing agent (hereinafter, referred to as “component (c)” in some cases), and a flux compound having an acid group (hereinafter, referred to as “component (d)” in some cases). The adhesive for a semiconductor of the present embodiment may contain a filler (hereinafter, referred to as “component (e)” in some cases) as necessary.

The exothermic calorific value at 60 to 155° C. of a DSC curve obtained by differential scanning calorimetry (DSC) of the adhesive for a semiconductor of the present embodiment is 20 J/g or less. Here, the differential scanning calorimetry is performed by setting the weight of the adhesive for a semiconductor as a sample to 10 mg, setting the measurement temperature range to 30 to 300° C., setting the temperature increase rate to 10° C./min, and heating the adhesive for a semiconductor in air or in a nitrogen atmosphere. The exothermic calorific value is calculated by integration of a peak area.

A conventional adhesive for a semiconductor has an exothermic peak in a temperature range of 60 to 155° C. of the DSC curve. The exothermic heat in this temperature range is speculated to be exothermic heat derived from reaction between the thermosetting resin and the flux compound in the adhesive for a semiconductor, and it is speculated that, when this reaction progresses, the adhesive for a semiconductor is partially cured to reduce fluidity. On the other hand, usually, temporary fixing of the semiconductor chip with the adhesive for a semiconductor is performed by heating the adhesive for a semiconductor, for example, to 60 to 155° C. to cause the adhesive for a semiconductor to properly flow. Therefore, when the conventional adhesive for a semiconductor is used in a process of mounting a plurality of semiconductor chips onto a member to be mounted (such as a semiconductor chip, a semiconductor wafer, or a wiring circuit substrate) and temporarily fixing the plurality of semiconductor chips, and then performing curing and sealing collectively under a pressurized condition, the thermosetting resin and the flux compound in the adhesive for a semiconductor react with each other during temporarily fixing the semiconductor chips so that curing of the adhesive for a semiconductor partially progresses, and it is speculated that the adhesive for a semiconductor does not sufficiently flow during collective curing under a pressurized condition. On the other hand, the adhesive for a semiconductor of the present embodiment has an exothermic calorific value at 60 to 155° C. of the DSC curve of 20 J/g or less, and curing is difficult to progress in a temperature range (for example, 60 to 155° C.) at which the semiconductor chip is temporarily fixed. Therefore, by using the adhesive for a semiconductor of the present embodiment in the above-described process, the plurality of semiconductor chips can be temporarily fixed while sufficient fluidity of the adhesive for a semiconductor is maintained, and a reduction in generation of voids during collective curing in the sealing step and elimination of voids generated in the step before the sealing step can be achieved. Further, generation of voids is reduced, and as a result, even when heating is performed at a temperature (for example, 260° C.) equal to or higher than the melting point of the connection portion in a reflow process after absorption of moisture, it is expected that troubles (such as peeling of the adhesive for a semiconductor and an electrical connection failure at the connection portion) are difficult to occur. That is, according to the adhesive for a semiconductor of the present embodiment, there is a tendency that moisture absorption and reflow reliability (reflow resistance) can be improved in the manufacturing of a semiconductor device.

The exothermic calorific value at 60 to 155° C. of the DSC curve is preferably 15 J/g or less and more preferably 10 J/g or less, from the viewpoint of easily obtaining the effects of the present disclosure. The exothermic calorific value at 60 to 155° C. of the DSC curve may be 20% or less, 15% or less, or 10% or less of the exothermic calorific value at 60 to 280° C., from the viewpoint of easily obtaining the effects of the present disclosure. The exothermic calorific value at 60 to 280° C. of the DSC curve may be 50 J/g or more or 100 J/g or more, may be 200 J/g or less or 180 J/g or less, and may be 50 to 200 J/g, 100 to 200 J/g, or 100 to 180 J/g, from the viewpoint of easily obtaining the effects of the present disclosure. It is preferable that the DSC curve does not have an exothermic peak at which the onset temperature is 155° C. or lower from the viewpoint of easily obtaining the effects of the present disclosure. That is, the onset temperature at the exothermic peak of the DSC curve is preferably 155° C. or higher, more preferably 165° C. or higher, and even more preferably 170° C. or higher, from the viewpoint of easily obtaining the effects of the present disclosure.

The adhesive for a semiconductor of the present embodiment showing the above-described DSC curve can be obtained, for example, by blending the curing agent and the flux compound so that the ratio of the number of moles of the acid group in the total amount of the flux compound with respect to the number of moles of the reactive group (a group reacting with the acid group of the flux compound) in the total amount of the curing agent reaches 0.01 to 4.8. That is, the method for producing the adhesive for a semiconductor of the present embodiment includes a step of mixing a thermoplastic resin, a thermosetting resin, a curing agent, and a flux compound having an acid group, and in this step, the curing agent and the flux compound are blended so that the ratio of the number of moles of the acid group in the total amount of the flux compound with respect to the number of moles of the reactive group in the total amount of the curing agent reaches 0.01 to 4.8.

The present inventors speculate the reason why the adhesive for a semiconductor showing the above-described DSC curve is obtained by setting the molar ratio of the curing agent and the flux compound in the above range as follows. That is, as described above, the thermosetting resin and the flux compound in the adhesive for a semiconductor react with each other in a temperature range of 60 to 155° C. However, when the molar ratio of the curing agent and the flux compound is in the above range, it is speculated that the flux compound forms a salt with the curing agent before reacting with the thermosetting resin so as to be stabilized. Therefore, it is speculated that the reaction between the thermosetting resin and the flux compound is suppressed, and as a result, the adhesive for a semiconductor showing the above-described DSC curve is obtained.

Furthermore, the adhesive for a semiconductor of the present embodiment has a minimum melt viscosity of a viscosity curve obtained by shear viscosity measurement with a rotary rheometer of 2000 Pa·s or more. The shear viscosity measurement with a rotary rheometer shown here is performed by setting the thickness of the sample before curing the adhesive for a semiconductor to 200 to 1500 μm, setting the measurement temperature range to 30 to 180° C., setting the temperature increase rate to 10° C./min, and heating the adhesive for a semiconductor. Note that, in a case where the temperature (melt temperature) at which the adhesive for a semiconductor has the minimum melt viscosity of higher than 180° C., the measurement temperature range is set in a range including the melt temperature. More specifically, the minimum melt viscosity can be measured by the method described in Examples.

In a case where the onset temperature is 155° C. or higher, the conventional adhesive for a semiconductor had a minimum melt viscosity of less than 2000 Pa·s. When the viscosity at a high temperature state is low in this way, it is speculated that foaming and expansion of a volatile component contained in the adhesive for a semiconductor increase voids. On the other hand, the metal bonding of the connection portions is performed by high-temperature press-bonding after temporary fixing in a state where the adhesive for a semiconductor is heated at a temperature (for example, 260° C.) equal to or higher than the melting point of the connection portion to easily flow. Therefore, when the conventional adhesive for a semiconductor is used in a process of mounting a plurality of semiconductor chips onto a member to be mounted (such as a semiconductor chip, a semiconductor wafer, or a wiring circuit substrate) through an adhesive for a semiconductor and temporarily fixing the plurality of semiconductor chips, and then high-temperature press-bonding the plurality of semiconductor chips again at a temperature (for example, about 260° C.) equal to or higher than the melting point of the connection portion to perform metal bonding, melting point is performed in accordance with the flowing of the resin and high temperature is also rapidly applied to the volatile component contained in the adhesive for a semiconductor to start a curing reaction of the adhesive for a semiconductor, so that the adhesive for a semiconductor is gelled and foaming and expansion of the volatile component increase voids before the viscosity reaches a viscosity to suppress voids.

On the other hand, the adhesive for a semiconductor of the present embodiment has a minimum melt viscosity of 2000 Pa·s or more, and foaming and expansion of a volatile component in the high-temperature press-bonding process associated with metal bonding of the connection portion are easily suppressed. Therefore, by using the adhesive for a semiconductor of the present embodiment in the above-described process, the plurality of semiconductor chips can be temporarily fixed while sufficient fluidity of the adhesive for a semiconductor is maintained, the amount of voids can be suppressed also during high-temperature press-bonding, and a reduction in generation of voids during collective curing in the sealing step and elimination of voids generated in the step before the sealing step can be achieved. Further, generation of voids is reduced, and as a result, even when heating is performed at a temperature (for example, 260° C.) equal to or higher than the melting point of the connection portion in a reflow process after absorption of moisture, it is expected that troubles (such as peeling of the adhesive for a semiconductor and an electrical connection failure at the connection portion) are difficult to occur. That is, according to the adhesive for a semiconductor of the present embodiment, there is a tendency that moisture absorption and reflow reliability (reflow resistance) can be improved in the manufacturing of a semiconductor device.

The minimum melt viscosity of the viscosity curve is 2000 Pa·s or more, and is preferably 3000 Pas or more and more preferably 4000 Pa·s or more from the viewpoint of easily obtaining the effects of the present disclosure. Furthermore, from the viewpoint of preventing biting due to insufficient flowing of the resin to easily form metal bonding, the minimum melt viscosity is preferably 20000 Pas or less, more preferably 15000 Pas or less, and further preferably 10000 Pas or less. The temperature (melt temperature) at which the adhesive for a semiconductor has the minimum melt viscosity is preferably 135° C. or higher, more preferably 140° C. or higher, and further preferably 145° C. or higher, from the viewpoint of stability on heating.

Hereinafter, each component constituting the adhesive for a semiconductor of the present embodiment will be described.

(a) Thermoplastic Resin

The component (a) is not particularly limited, and examples thereof include a phenoxy resin, a polyimide resin, a polyamide resin, a polycarbodiimide resin, a cyanate ester resin, an acrylic resin, a polyester resin, a polyethylene resin, a polyethersulfone resin, a polyetherimide resin, a polyvinyl acetal resin, a urethane resin, and acrylic rubber. Among these, from the viewpoint of excellent heat resistance and film formability, a phenoxy resin, a polyimide resin, an acrylic resin, acrylic rubber, a cyanate ester resin, and a polycarbodiimide resin are preferable, and a phenoxy resin, a polyimide resin, and an acrylic resin are more preferable. These components (a) can be used singly or can also be used in combinations of two or more kinds thereof as a mixture or a copolymer.

The weight average molecular weight (Mw) of the component (a) is preferably 10000 or more, more preferably 40000 or more, and further preferably 60000 or more. According to such a component (a), film formability and heat resistance of the adhesive can be further improved. Furthermore, when the weight average molecular weight is 10000 or more, since flexibility is easily imparted to a film-shaped adhesive for a semiconductor, further excellent processability is easily obtained. Furthermore, the weight average molecular weight of the component (a) is preferably 1000000 or less and more preferably 500000 or less. According to such a component (a), since the viscosity of a film is decreased, embeddability in the bump becomes favorable, and mounting without much less voids can be performed. From these viewpoints, the weight average molecular weight of the component (a) is preferably 10000 to 1000000, more preferably 40000 to 500000, and further preferably 60000 to 500000.

Note that, in the present specification, the weight average molecular weight refers to a weight average molecular weight measured by using GPC (Gel Permeation Chromatography) in terms of polystyrene. An example of the measurement condition of the GPC method will be shown below.
Apparatus: HCL-8320GPC, UV-8320 (product name, manufactured by Tosoh Corporation), or HPLC-8020 (product name, manufactured by Tosoh Corporation)
Column: TSKgel superMultiporeHZ-M×2, or 2 pieces of GMHXL+1 piece of G-2000XL
Detector: RI or UV detector
Column temperature: 25 to 40° C.
Eluent: select a solvent in which the polymer component is soluble. Examples of the solvent include THF (tetrahydrofuran), DMF (N,N-dimethylformamide), DMA (N,N-dimethylacetoamide), NMP (N-methylpyrrolidone), and toluene. Note that, in the case of selecting a solvent having polarity, the concentration of phosphoric acid may be adjusted to 0.05 to 0.1 mol/L (usually 0.06 mol/L), and the concentration of LiBr may be adjusted to 0.5 to 1.0 mol/L (usually 0.63 mol/L).
Flow rate: 0.30 to 1.5 mL/min
Standard substance: polystyrene

A ratio C_{b}/Cₐ (mass ratio) of a content C_{b} of the component (b) with respect to a content Cₐ of the component (a) is preferably 0.01 or more, more preferably 0.1 or more, and further preferably 1 or more, and is preferably 5 or less, more preferably 4.5 or less, and further preferably 4 or less. When the ratio C_{b}/Cₐ is set to 0.01 or more, more favorable curability and a more favorable adhesive force are obtained, and when the ratio C_{b}/Cₐ is set to 5 or less, more favorable film formability is obtained. From these viewpoints, the ratio C_{b}/Cₐ is preferably 0.01 to 5, more preferably 0.1 to 4.5, and further preferably 1 to 4.

The glass transition temperature of the component (a) is preferably −50° C. or higher, more preferably −40° C. or higher, and further preferably −30° C. or higher, from the viewpoint of improvement of connection reliability and the like, and is preferably 220° C. or lower, more preferably 200° C. or lower, and further preferably 180° C. or lower, from the viewpoint of lamination properties and the like. The glass transition temperature of the component (a) is preferably −50 to 220° C., more preferably −40 to 200° C., and further preferably −30 to 180° C. According to the adhesive for a semiconductor containing such a component (a), in the mounting process on a wafer level, the wafer warpage amount can be further decreased, and heat resistance and film formability of the adhesive for a semiconductor can be further improved. The glass transition temperature of the component (a) can be measured by a differential scanning calorimeter (DSC).

The content of the component (a) is preferably 30% by mass or less, more preferably 25% by mass or less, and further preferably 20% by mass or less, on the basis of the total amount of solid contents of the adhesive for a semiconductor. When the content of the component (a) is 30% by mass or less, the adhesive for a semiconductor can obtain favorable reliability at the time of a temperature cycling test and can obtain a favorable adhesive force at a reflow temperature around 260° C. after the adhesive absorbs moisture. Furthermore, the content of the component (a) is preferably 1% by mass or more, more preferably 3% by mass or more, and further preferably 5% by mass or more, on the basis of the total amount of solid contents of the adhesive for a semiconductor. When the content of the component (a) is 1% by mass or more, in the mounting process on a wafer level, the adhesive for a semiconductor can further decrease the wafer warpage amount and can further improve heat resistance and film for liability of the adhesive for a semiconductor. Furthermore, when the content of the component (a) is 5% by mass or more, generation of burr and chipping at the time of trimming into a wafer shape can be suppressed. The content of the component (a) is preferably 1 to 30% by mass and more preferably 3 to 30% by mass, further preferably 5 to 30% by mass, on the basis of the total amount of solid contents of the adhesive for a semiconductor, from the above viewpoint and the viewpoint of easily imparting flexibility to a film-shaped adhesive for a semiconductor and easily obtaining further excellent processability. Note that, the “solid contents of the adhesive for a semiconductor” correspond to the amount obtained by subtracting the amount of the solvent contained in the adhesive for a semiconductor from the total amount of the adhesive for a semiconductor. In the present specification, the “solid contents of the adhesive for a semiconductor” may be rephrased as the “total amount of the components (a) to (e)”.

(b) Thermosetting Resin

As the component (b), any thermosetting resin having two or more reactive groups in the molecule can be used without particular limitation. When the adhesive for a semiconductor contains a thermosetting resin, the adhesive can be cured by heating, the cured adhesive exhibits high heat resistance and a high adhesive force to a chip, and excellent reflow resistance is obtained.

Examples of the component (b) include an epoxy resin, a phenol resin, an imide resin, a urea resin, a melamine resin, a silicon resin, a (meth)acrylic compound, and a vinyl compound. Among these, from the viewpoint of excellent heat resistance (reflow resistance) and storage stability, an epoxy resin, a phenol resin, and an imide resin are preferable, an epoxy resin and an imide resin are more preferable, and an epoxy resin is further preferable. These components (b) can be used singly or can also be used in combinations of two or more kinds thereof as a mixture or a copolymer. Among the conventional adhesives for a semiconductor, particularly, in a case where the thermosetting resin is an epoxy resin, a melamine resin, or a urea resin, there is a tendency that the reaction with a flux compound described below is easy to progress at a temperature range of 60 to 155° C. and partial curing progresses before collective curing; however, in the present embodiment, even in a case where the thermosetting resin includes at least one resin selected from the group consisting of an epoxy resin, a melamine resin, and a urea resin, such a reaction and partial curing are less likely to occur.

As the epoxy resin and the imide resin, for example, a bisphenol A type epoxy resin, a bisphenol F type epoxy resin, a naphthalene type epoxy resin, a phenol novolak type epoxy resin, a cresol novolak type epoxy resin, a phenol aralkyl type epoxy resin, a biphenyl type epoxy resin, a triphenylmethane type epoxy resin, a dicyclopentadiene type epoxy resin, and various polyfunctional epoxy resins, a nadimide resin, an allylnadimide resin, a maleimide resin, an amide imide resin, an imide acrylate resin, various polyfunctional imide resins, and various polyimide resins can be used. These can be used singly or in combinations of two or more kinds thereof as a mixture.

From the viewpoint of preventing the component (b) from decomposing to generate a volatile component during connection at a high temperature, the component (b) having a rate of thermal weight loss at 250° C. of 5% or less is preferably used in a case where the temperature during connection is 250° C., and the component (b) having a rate of thermal weight loss at 300° C. of 5% or less is preferably used in a case where the temperature during connection is 300° C.

It is preferable that the component (b) does not substantially contain an epoxy resin that is a liquid at 35° C. (for example, the content of the epoxy resin that is a liquid at 35° C. is 0.1 parts by mass or less with respect to 100 parts by mass of the component (b)). In this case, mounting can be performed without the epoxy resin in a liquid state decomposed and volatilized during thermal press-bonding, and outgas contamination at a chip periphery is suppressed, so that further excellent package throughput properties are easily obtained.

The content of the component (b) is, for example, 5% by mass or more, preferably 15% by mass or more, and more preferably 30% by mass or more, on the basis of the total amount of solid contents of the adhesive for a semiconductor. The content of the component (b) is, for example, 80% by mass or less, preferably 70% by mass or less, and more preferably 60% by mass or less, on the basis of the total amount of solid contents of the adhesive for a semiconductor. The content of the component (b) is, for example, 5 to 80% by mass, preferably 15 to 70% by mass, and more preferably 30 to 60% by mass, on the basis of the total amount of solid contents of the adhesive for a semiconductor.

(c) Curing Agent

The component (c) may be a curing agent that can for n a salt with a fluxing agent described below. Examples of the component (c) include amine-based curing agents (amines) and imidazole-based curing agents (imidazoles). When the component (c) includes an amine-based curing agent or an imidazole-based curing agent, fluxing activity to prevent generation of an oxidized film in the connection portion is exhibited, and connection reliability and insulation reliability can be improved. Furthermore, when the component (c) includes an amine-based curing agent or an imidazole-based curing agent, there is a tendency that storage stability is further improved and decomposition or degradation due to absorption of moisture is difficult to occur. Further, when the component (c) includes an amine-based curing agent or an imidazole-based curing agent, the curing rate is easy to adjust and curing can be easily attained in a short time due to latent curability to improve productivity.

Hereinafter, respective curing agents will be described.

(i) Amine-Based Curing Agent

As the amine-based curing agent, for example, dicyandiamide can be used.

The content of the amine-based curing agent is preferably 0.1 parts by mass or more, and is preferably 10 parts by mass or less and more preferably 5 parts by mass or less, with respect to 100 parts by mass of the component (b). When the content of the amine-based curing agent is 0.1 parts by mass or more, there is a tendency that curability is improved, and when the content thereof is 10 parts by mass or less, there is a tendency that the adhesive for a semiconductor is not cured before metal bonding is formed and a connection failure is less likely to occur. From these viewpoints, the content of the amine-based curing agent is preferably 0.1 to 10 parts by mass and more preferably 0.1 to 5 parts by mass, with respect to 100 parts by mass of the component (b).

(ii) Imidazole-Based Curing Agent

Examples of the imidazole-based curing agent include
2-phenylimidazole, 2-phenyl-4-methylimidazole,
1-benzyl-2-methylimidazole, 1-benzyl-2-phenylimidazole,
1-cyanoethyl-2-undecylimidazole, 1-cyano-2-phenylimidazole,
1-cyanoethyl-2-undecylimidazole trimellitate,
1-cyanoethyl-2-phenylimidazolium trimellitate,
2,4-diamino-6-[2′-methylimidazolyl-(1′)]-ethyl-s-triazine,
2,4-diamino-6-[2′-undecylimidazolyl-(1′)]-ethyl-s-triazine,
2,4-diamino-6-[2′-ethyl-4′-methylimidazolyl-(1′)]-ethyl-s-triazine,
2,4-diamino-6-[2′-methylimidazolyl-(1′)]-ethyl-s-triazine isocyanuric acid adducts, 2-phenylimidazole isocyanuric acid adducts,
2-phenyl-4,5-dihydroxymethylimidazole,
2-phenyl-4-methyl-5-hydroxymethylimidazole, and adducts of epoxy resins and imidazoles. Among these, from the viewpoint of excellent curability, storage stability, and connection reliability,
1-cyanoethyl-2-undecylimidazole, 1-cyano-2-phenylimidazole,
1-cyanoethyl-2-undecylimidazole trimellitate,
1-cyanoethyl-2-phenylimidazolium trimellitate,
2,4-diamino-6-[2′-methylimidazolyl-(1′)]-ethyl-s-triazine,
2,4-diamino-6-[2′-ethyl-4′-methylimidazolyl-(1′)]-ethyl-s-triazine,
2,4-diamino-6-[2′-methylimidazolyl-(1′)]-ethyl-s-triazine isocyanuric acid adducts, 2-phenylimidazole isocyanuric acid adducts,
2-phenyl-4,5-dihydroxymethylimidazole, and
2-phenyl-4-methyl-5-hydroxymethylimidazole are preferable. These can be used singly or in combinations of two or more kinds thereof. Furthermore, these may also be formed into a microcapsulized latent curing agent.

The content of the imidazole-based curing agent is preferably 0.1 parts by mass or more, and is preferably 10 parts by mass or less, more preferably 5 parts by mass or less, and further preferably 2.3 parts by mass or less, with respect to 100 parts by mass of the component (b). When the content of the imidazole-based curing agent is 0.1 parts by mass or more, there is a tendency that curability is improved. When the content of the imidazole-based curing agent is 10 parts by mass or less, the adhesive for a semiconductor is not cured before metal bonding is formed, a connection failure is less likely to occur, and generation of voids in the curing process under a pressurized atmosphere is easily suppressed. From these viewpoints, the content of the imidazole-based curing agent is preferably 0.1 to 10 parts by mass, more preferably 0.1 to 5 parts by mass, and more preferably 0.1 to 2.3 parts by mass, with respect to 100 parts by mass of the component (b).

The component (c) can be used singly or in combinations of two or more kinds thereof as a mixture. For example, the imidazole-based curing agent may be used singly or in combination with the amine-based curing agent. As the component (c), a curing agent, which functions as the curing agent of the component (b), other than the above-described curing agents can be used.

The content of the component (c) is preferably 0.5 parts by mass or more, and is preferably 20 parts by mass or less, more preferably 6 parts by mass or less, and further preferably 4 parts by mass or less, with respect to 100 parts by mass of the component (b). In a case where the content of the component (c) is 0.5 parts by mass or more, there is a tendency that curing sufficiently progresses. In a case where the content of the component (c) is 20 parts by mass or less, an increase in the number of reactive sites caused by rapid curing progressing is suppressed to shorten a molecular chain, and the remaining of unreacted groups is suppressed to tend to be likely to suppress deterioration in reliability, and in addition thereto, the remaining of voids during curing under a pressurized atmosphere is likely to be suppressed. From these viewpoints, the content of the component (c) is preferably 0.2 to 20 parts by mass, more preferably 0.5 to 6 parts by mass, and further preferably 0.5 to 4 parts by mass, with respect to 100 parts by mass of the component (b).

The content of the component (c) is preferably 0.5% by mass or more, and is preferably 2.3% by mass or less, more preferably 2.0% by mass or less, and further preferably 1.5% by mass or less, on the basis of the total amount of solid contents of the adhesive for a semiconductor. In a case where the content of the component (c) is 0.5% by mass or more, there is a tendency that curing sufficiently progresses. In a case where the content of the component (c) is 2.3% by mass or less, an increase in the number of reactive sites caused by rapid curing progressing is suppressed to shorten a molecular chain, and the remaining of unreacted groups is suppressed to tend to be likely to suppress deterioration in reliability, and in addition thereto, the remaining of voids during curing under a pressurized atmosphere is likely to be suppressed. From these viewpoints, the content of the component (c) is preferably 0.5 to 2.3% by mass and more preferably 0.5 to 2.0% by mass, on the basis of the total amount of solid contents of the adhesive for a semiconductor.

In a case where the adhesive for a semiconductor contains an amine-based curing agent as the component (c), fluxing activity to remove an oxidized film can be exhibited to improve connection reliability.

(d) Flux Compound

The component (d) is a compound having fluxing activity (activity to remove oxides and impurities), and is, for example, an organic acid. When the adhesive for a semiconductor contains the component (d), an oxidized film of the metal of the connection portion and coating by an OSP treatment can be removed, and thus excellent connection reliability is easily obtained. As the component (d), the flux compound (for example, organic acid) may be used singly or two or more kinds of flux compounds (for example, organic acids) may be used in combination.

The component (d) has one or more acid groups. The acid group is preferably a carboxyl group. In a case where the component (d) is a compound having a carboxyl group (for example, carboxylic acid), further excellent connection reliability is easily obtained. In a case where the component (d) is a compound having a carboxyl group (for example, carboxylic acid), from the viewpoint of easily obtaining the effects of the present disclosure, the component (b) is preferably at least one thermosetting resin selected from the group consisting of an epoxy resin, a urethane resin, and a urea resin, and the component (c) is preferably at least one curing agent selected from the group consisting of an amine-based curing agent and an imidazole-based curing agent.

The component (d) is preferably a compound having one to three acid groups and more preferably a compound having one to three carboxyl groups as the acid group. The component (d) preferably includes at least one selected from the group consisting of monocarboxylic acid, dicarboxylic acid, and tricarboxylic acid. In the case of using the component (d) having one to three carboxyl groups, compared to the case of using a compound having four or more carboxyl groups, an increase in viscosity of the adhesive for a semiconductor during preservation, working on connection, and the like can be further suppressed, and the connection reliability of the semiconductor device can be further improved.

The component (d) more preferably includes at least one selected from the group consisting of monocarboxylic acid and dicarboxylic acid. For example, in a case where the thermosetting resin is an epoxy resin, a urethane resin, or a urea resin, a part of the component (b) and a part of the component (d) react with each other during polymerization (curing) by heat to generate an ester. In the case of using monocarboxylic acid having one carboxyl group, ester bond derived from this ester is less likely to be present in the polymerization main chain. Therefore, even when ester hydrolysis occurs due to absorption of moisture, the molecular chain is not considerably reduced. Therefore, a sticking force (for example, a sticking force to silicon) after absorption of moisture and a bulk strength of a cured product can be maintained at a high level, and the reflow resistance and the connection reliability of the semiconductor device can be further improved. Furthermore, in the case of using dicarboxylic acid having two carboxyl groups, a part of the component (b) and a part of the component (d) react with each other to be actively incorporated in the polymerization main chain, and the component (d) is less likely to remain as a residue in a final cured product, and thus the number of acid groups in the cured product is reduced. Therefore, corrosion at the electrode portion of the semiconductor device and ion migration can be suppressed, and HAST resistance can be further improved.

The melting point of the component (d) is preferably 25° C. or higher, more preferably 90° C. or higher, and further preferably 100° C. or higher, and is preferably 230° C. or lower, more preferably 180° C. or lower, further preferably 170° C. or lower, and particularly preferably 160° C. or lower. In a case where the melting point of the component (d) is 230° C. or lower, fluxing activity is likely to be sufficiently exhibited before the curing reaction between the thermosetting resin and the curing agent. Therefore, according to the adhesive for a semiconductor containing such a component (d), the component (d) is melted at the time of chip mounting, and the oxidized film on the solder surface is removed, so that a semiconductor device further excellent in connection reliability can be attained. Furthermore, in a case where the melting point of the component (d) is 25° C. or higher, the reaction at room temperature is less likely to start, and storage stability is further excellent. From these viewpoints, the melting point of the component (d) is preferably 25 to 230° C., more preferably 90 to 180° C. or lower, further preferably 100 to 170° C., and particularly preferably 100 to 160° C.

The melting point of the component (d) can be measured using a standard melting point measurement apparatus. A small amount of a sample for measuring the melting point needs to be crushed into fine powder to reduce a difference in temperature in the sample. A container of the sample to be used is often a capillary tube whose one end is closed; in some measurement apparatuses, a sample is sandwiched between two cover glasses for a microscope instead of a container. Furthermore, rapid increase in temperature generates temperature gradient between the sample and a thermometer to produce an error in the measurement; therefore, the temperature is desirably raised at an increase rate of 1° C./min or less when the melting point is measured.

The sample is prepared as fine powder as described above, and thus the sample before melting is opaque due to diffuse reflection on the surface of the sample. Usually, the temperature when the sample appears to be transparent is defined as the lower limit point of the melting point, and the temperature when the sample is completely melted is defined as the upper limit point. A variety of measurement apparatuses exist, and an apparatus most typically used is an apparatus including a double tube thermometer in which a capillary tube containing a sample is mounted on the thermometer and is heated in a warm bath. To attach the capillary tube to the double tube thermometer, a viscous liquid is used as a liquid for the warm bath, concentrated sulfuric acid or silicone oil is often used, and the capillary tube is attached to the thermometer such that the sample is close to the bulb at the tip of the thermometer. Furthermore, as the melting point measurement apparatus, a melting point measurement apparatus for heating a sample using a metal heat block and automatically determining the melting point while measuring light transmittance and controlling heating can also be used.

Note that, in the present specification, the expression “melting point is 230° C. or lower” indicates that the upper limit point of the melting point is 230° C. or lower, and the expression “melting point is 25° C. or higher” indicates that the lower limit point of the melting point is 25° C. or higher.

Specific examples of the component (d) include malonic acid, methylmalonic acid, dimethylmalonic acid, ethylmalonic acid, allylmalonic acid, 2,2′-thiodiacetic acid, 3,3′-thiodipropionic acid, 2,2′-(ethylenedithio)diacetic acid, 3,3′-dithiopropionic acid, 2-ethyl-2-hydroxybutyric acid, dithiodiglycolic acid, diglycolic acid, acetylenedicarboxylic acid, maleic acid, malic acid, 2-isopropylmalic acid, tartaric acid, itaconic acid, 1,3-acetonedicarboxylic acid, tricarballylic acid, muconic acid, β-hydromuconic acid, succinic acid, methylsuccinic acid, dimethylsuccinic acid, glutaric acid, α-ketoglutaric acid, 2-methylglutaric acid, 3-methylglutaric acid, 2,2-dimethylglutaric acid, 3,3-dimethylglutaric acid, 2,2-bis(hydroxymethyl)propionic acid, citric acid, adipic acid, 3-tert-butyladipic acid, pimelic acid, phenyloxalic acid, phenylacetic acid, nitrophenylacetic acid, phenoxyacetic acid, nitrophenoxyacetic acid, phenylthioacetic acid, hydroxyphenylacetic acid, dihydroxyphenylacetic acid, mandelic acid, hydroxymandelic acid, dihydroxymandelic acid, 1,2,3,4-butanetetracarboxylic acid, suberic acid, 4,4′-dithiodibutyric acid, cinnamic acid, nitrocinnamic acid, hydroxycinnamic acid, dihydroxycinnamic acid, coumaric acid, phenylpyruvic acid, hydroxyphenylpyruvic acid, caffeic acid, homophthalic acid, tolylacetic acid, phenoxypropionic acid, hydroxyphenylpropionic acid, benzyloxyacetic acid, phenyllactic acid, tropic acid, 3-(phenylsulfonyl)propionic acid, 3,3-tetramethyleneglutaric acid, 5-oxoazelaic acid, azelaic acid, phenylsuccinic acid, 1,2-phenylenediacetic acid, 1,3-phenylenediacetic acid, 1,4-phenylenediacetic acid, benzylmalonic acid, sebacic acid, dodecanoic diacid, undecanoic diacid, diphenylacetic acid, benzilic acid, dicyclohexylacetic acid, tetradecane diacid, 2,2-diphenylpropionic acid, 3,3-diphenylpropionic acid, 4,4-bis(4-hydroxypheny)valeric acid (diphenolic acid), pimaric acid, palustric acid, isopimaric acid, abietic acid, dehydroabietic acid, neoabietic acid, agathic acid, benzoic acid, 2-hydroxybenzoic acid, 3-hydroxybenzoic acid, 4-hydroxybenzoic acid, 2,3-dihydroxybenzoic acid, 2,4-dihydroxybenzoic acid, 2,5-dihydroxybenzoic acid, 2,6-dihydroxybenzoic acid, 3,4-dihydroxybenzoic acid, 2,3,4-trihydroxybenzoic acid, 2,4,6-trihydroxybenzoic acid, 3,4,5-trihydroxybenzoic acid, 1,2,3-benzenetricarboxylic acid, 1,2,4-benzenetricarboxylic acid, 1,3,5-benzenetricarboxylic acid, 2-[bis(4-hydroxypheny)methyl]benzoic acid, 1-naphthoic acid, 2-naphthoic acid, 1-hydroxy-2-naphthoic acid, 2-hydroxy-1-naphthoic acid, 3-hydroxy-2-naphthoic acid, 6-hydroxy-2-naphthoic acid, 1,4-dihydroxy-2-naphthoic acid, 3,5-dihydroxy-2-naphthoic acid, 3,7-dihydroxy-2-naphthoic acid, 2,3-naphthalenedicarboxylic acid, 2,6-naphthalenedicarboxylic acid, 2-phenoxybenzoic acid, biphenyl-4-carboxylic acid, biphenyl-2-carboxylic acid, and 2-benzoylbenzoic acid. Among these, from the viewpoint of easily obtaining excellent fluxing activity and the viewpoint of easily obtaining the effects of the present disclosure, benzilic acid and diphenylacetic acid are preferable.

The content of the component (d) is preferably 0.1% by mass or more, and is preferably 10% by mass or less, more preferably 5% by mass or less, and further preferably 2% by mass or less, on the basis of the total amount of solid contents of the adhesive for a semiconductor. The content of the component (d) is preferably 0.1 to 10% by mass, more preferably 0.1 to 5% by mass, and further preferably 0.1 to 2% by mass, on the basis of the total amount of solid contents of the adhesive for a semiconductor, from the viewpoint of connection reliability and reflow resistance at the time of manufacturing a semiconductor device. Note that, in a case where a compound having fluxing activity corresponds to the components (a) to (c), this compound is regarded to also correspond to the component (d), and then the content of the component (d) is calculated. The same applies to the number of moles of the acid group described below, and the like.

In the present embodiment, the ratio of the number of moles of the acid group in the total amount of the component (d) with respect to the number of moles of the reactive group in the total amount of the component (c) is preferably 0.01 or more and is preferably 4.8 or less. The molar ratio is more preferably 0.1 or more and further preferably 0.5 or more, and is more preferably 4.0 or less and further preferably 3.0 or less.

In a case where the component (d) includes at least one selected from the group consisting of monocarboxylic acid, dicarboxylic acid, and tricarboxylic acid, it is preferable that the ratio of the number of moles of the acid group in the total amount of the component (d) with respect to the number of moles of the reactive group in the total amount of the component (c) is 0.01 to 4.8, the ratio of the number of moles of the monocarboxylic acid with respect to the number of moles of the reactive group in the total amount of the component (c) is 0.01 to 4.8, the ratio of the number of moles of the dicarboxylic acid with respect to the number of moles of the reactive group in the total amount of the component (c) is 0.01 to 2.4, and the ratio of the number of moles of the tricarboxylic acid with respect to the number of moles of the reactive group in the total amount of the component (c) is 0.01 to 1.6, and it is preferable that the ratio of the number of moles of the monocarboxylic acid with respect to the number of moles of the reactive group in the total amount of the component (c) is 0.5 to 3.0, the ratio of the number of moles of the dicarboxylic acid with respect to the number of moles of the reactive group in the total amount of the component (c) is 0.25 to 1.5, and the ratio of the number of moles of the tricarboxylic acid with respect to the number of moles of the reactive group in the total amount of the component (c) is 0.5/3 to 1.0.

(e) Filler

The adhesive for a semiconductor of the present embodiment may contain a filler (component (e)) as necessary. The component (e) can control the viscosity of the adhesive for a semiconductor, physical properties of a cured product of the adhesive for a semiconductor, and the like. Specifically, according to the component (e), for example, suppression of generation of voids during connection, a decrease in moisture absorbing rate of the cured product of the adhesive for a semiconductor, and the like can be achieved.

As the component (e), an insulating inorganic filler, a whisker, a resin filler, and the like can be used. Furthermore, the component (e) may be used singly or may be in combination of two or more kinds thereof.

Examples of the insulating inorganic filler include glass, silica, alumina, titanium oxide, carbon black, mica, and boron nitride. Among these, silica, alumina, titanium oxide, and boron nitride are preferable, and silica, alumina, and boron nitride are more preferable.

Examples of the whisker include aluminum borate, aluminum titanate, zinc oxide, calcium silicate, magnesium sulfate, and boron nitride.

Examples of the resin filler include fillers composed of resins such as polyurethane and polyimide.

The resin filler has a thermal expansion coefficient lower than those of organic components (such as the epoxy resin and the curing agent), and thus is excellent in an effect of improving connection reliability. Furthermore, according to the resin filler, the viscosity of the adhesive for a semiconductor can be easily adjusted. Furthermore, the resin filler has a better function to relax stress than an inorganic filler does.

The inorganic filler has a thermal expansion coefficient lower than that of the resin filler, and according to the inorganic filler, a decrease in thermal expansion coefficient of an adhesive composition can be attained. Furthermore, many inorganic fillers are general-purpose products having a controlled particle diameter, and are also preferable in adjustment of the viscosity.

Since the resin filler and the inorganic filler have their own advantageous effects, depending on use application, one of these may be used, or both may be used by mixing to demonstrate the functions of these fillers.

The shape, the particle diameter, and the content of the component (e) are not particularly limited. Furthermore, the component (e) may be surface-treated to have appropriately controlled physical properties.

The content of the component (e) is preferably 10% by mass or more and more preferably 15% by mass or more, and is preferably 80% by mass or less and more preferably 60% by mass or less, on the basis of the total amount of solid contents of the adhesive for a semiconductor. The content of the component (e) is preferably 10 to 80% by mass and more preferably 15 to 60% by mass, on the basis of the total amount of solid contents of the adhesive for a semiconductor.

The component (e) is preferably composed of an insulating material. When the component (e) is composed of a conductive substance (such as solder, gold, silver, and copper), insulation reliability (particularly, HAST resistance) may be deteriorated.

(Other Components)

The adhesive for a semiconductor of the present embodiment may be blended with additives such as an antioxidant, a silane coupling agent, a titanium coupling agent, a leveling agent, and an ion trap agent. These can be used singly or in combinations of two or more kinds thereof. The blending amounts of these may be appropriately adjusted to demonstrate the effects of the respective additives.

The adhesive for a semiconductor of the present embodiment may be formed into a film. In this case, a pre-applied method can improve workability in the case of sealing of a gap between a semiconductor chip and a wiring substrate or gaps between a plurality of semiconductor chips. An example of a method for producing the adhesive for a semiconductor of the present embodiment molded into a film (film-shaped adhesive) will be shown below.

First, the component (a), the component (b), the component (c), and the component (d), as well as the component (e) which is added as necessary and the like are added to an organic solvent, and are dissolved or dispersed by stirring and mixing, kneading, or the like, to prepare a resin varnish. Thereafter, the resin varnish is applied onto a base material film subjected to a releasing treatment by using a knife coater, a roll coater, an applicator, or the like, and then the organic solvent is removed by heating so that a film-shaped adhesive can be formed on the base material film.

The thickness of the film-shaped adhesive is not particularly limited, and for example, is preferably 0.5 to 1.5 times, more preferably 0.6 to 1.3 times, and further preferably 0.7 to 1.2 times the height of a bump before connection.

When the thickness of the film-shaped adhesive is 0.5 times or more the height of the bump, generation of voids caused by not filling the adhesive can be sufficiently suppressed, and connection reliability can be further improved. Furthermore, when the thickness is 1.5 times or less, the amount of the adhesive to be extruded from a chip connection region during connection can be sufficiently suppressed, and thus adhesion of the adhesive to unnecessary portions can be sufficiently prevented. When the thickness of the film-shaped adhesive is more than 1.5 times, a large amount of the adhesive has to be removed from the bumps, so that failure in conduction is likely to occur. Furthermore, removal of a large amount of the resin from the bumps weakened because of a narrower pitch and an increasing number of pins (reduction in a bump diameter) is not preferable because the removal damages the bumps significantly.

Since a standard height of the bump is 5 to 100 μm, the thickness of the film-shaped adhesive is preferably 2.5 to 150 μm and more preferably 3.5 to 120 μm.

The organic solvent used to prepare the resin varnish is preferably those that can uniformly dissolve or disperse the respective components, and examples thereof include dimethylformamide, dimethylacetoamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combinations of two or more kinds thereof. In preparation of the resin varnish, stirring and mixing or kneading can be performed, for example, by using a stirrer, a mortar machine, a triple roll mill, a ball mill, a bead mill, or a homo-disper.

The base material film is not particularly limited as long as it has heat resistance to endure a heating condition when the organic solvent is volatilized, and examples thereof include polyolefin films such as polypropylene films and polymethylpentene films, polyester films such as polyethylene terephthalate films and polyethylene naphthalate films, polyimide films, and polyether imide films. The base material film is not limited to a single layer composed of one of these films, and may be a multi-layer film composed of two or more kinds of materials.

The drying condition when the organic solvent is volatilized from the resin varnish applied onto the base material film is preferably set to a drying condition in which the organic solvent sufficiently volatilizes, and specifically, drying is preferably performed by heating at 50 to 200° C. for 0.1 to 90 minutes. The organic solvent is preferably removed to 1.5% by mass or less with respect to the total amount of the film-shaped adhesive.

Furthermore, the adhesive for a semiconductor of the present embodiment may be formed directly on a wafer. Specifically, for example, a layer composed of the adhesive for a semiconductor may be formed directly on a wafer by applying the resin varnish onto a wafer directly by spin coating to form a film, and then removing the organic solvent.

From the viewpoint of facilitating temporary fixing of the semiconductor chip in a temperature range of 60 to 155° C., the adhesive for a semiconductor of the present embodiment preferably has a melt viscosity at 80° C. of 5000 to 30000 Pa·s and a melt viscosity at 130° C. of 2500 to 20000 Pa·s, more preferably has a melt viscosity at 80° C. of 8000 to 27000 Pa·s and a melt viscosity at 130° C. of 3500 to 15000 Pa·s, and further preferably has a melt viscosity at 80° C. of 10000 to 25000 Pa·s and a melt viscosity at 130° C. of 4500 to 10000 Pa·s. The above-described melt viscosity can be measured by the method described in Examples.

The adhesive for a semiconductor of the present embodiment having been described above can be suitably used in a process of curing the adhesive for a semiconductor by applying heat under a pressurized atmosphere, and can be suitably used particularly in a process of mounting a plurality of semiconductor chips onto a member to be mounted (such as a semiconductor chip, a semiconductor wafer, or a wiring circuit substrate) through an adhesive for a semiconductor and temporarily fixing the plurality of semiconductor chips, then high-temperature press-bonding the plurality of semiconductor chips again at a temperature (for example, about 260° C.) equal to or higher than the melting point of the connection portion to perform metal bonding, and performing curing and sealing the adhesive for a semiconductor collectively. In the case of the adhesive for a semiconductor of the present embodiment in this process, generation of voids during temporary fixing and during metal bonding by high-temperature press-bonding can be suppressed, voids inside the adhesive are easily removed by pressurizing, and further excellent reflow resistance is easily obtained.

<Semiconductor Device>

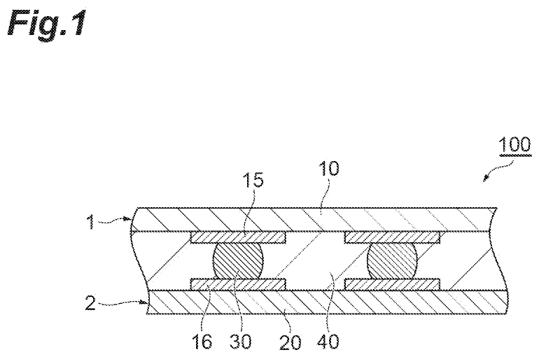

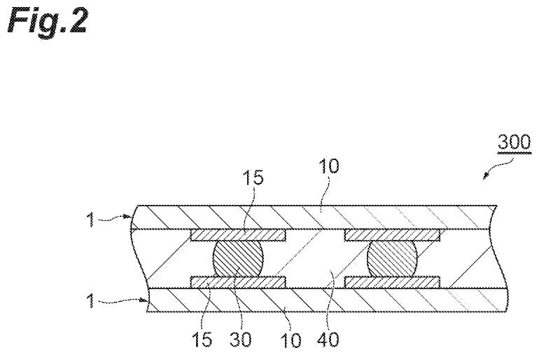

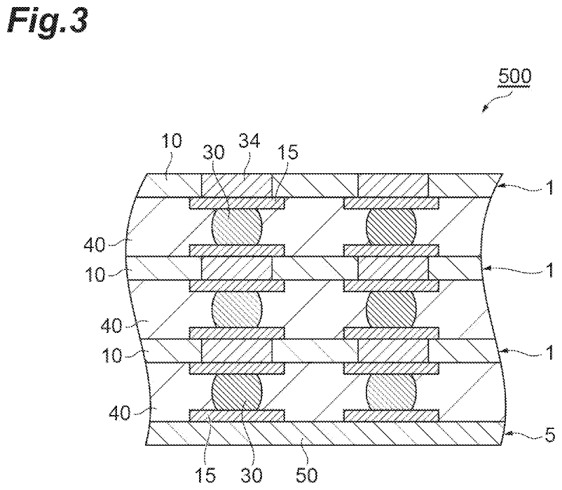

A semiconductor device of the present embodiment is a semiconductor device in which connection portions of a semiconductor chip and a wiring circuit substrate are electrically connected to each other or a semiconductor device in which connection portions of a plurality of semiconductor chips are electrically connected to each other. In this semiconductor device, at least a part of the connection portion is sealed with a cured product of the adhesive for a semiconductor cured by applying heat under a pressurized atmosphere. Hereinafter, the semiconductor device of the present embodiment will be described with reference to FIG. 1, FIG. 2, and FIG. 3. Each of FIG. 1, FIG. 2, and FIG. 3 is a cross-sectional view illustrating an embodiment of a semiconductor device manufactured by a method of an embodiment described below.

FIG. 1 is a schematic cross-sectional view illustrating a COB connection mode between a semiconductor chip and a substrate. A semiconductor device 100 illustrated in FIG. 1 includes a semiconductor chip 1, a substrate 2 (wiring circuit substrate), and an adhesive layer 40 interposed therebetween. In the case of the semiconductor device 100, the semiconductor chip 1 has a semiconductor chip main body 10, wires or bumps 15 disposed on the surface of the semiconductor chip main body 10 on the substrate 2 side, and solders 30 as connection portions disposed on the wires or bumps 15. The substrate 2 has a substrate main body 20 and wires or bumps 16 as connection portions disposed on the surface of the substrate main body 20 on the semiconductor chip 1 side. The solders 30 of the semiconductor chip 1 and the wires or bumps 16 of the substrate 2 are electrically connected to each other by metal bonding. The semiconductor chip 1 and the substrate 2 are flip chip connected to each other through the wires or bumps 16 and the solders 30. The wires or bumps 15 and 16 and the solders 30 are sealed with the adhesive layer 40 to be shielded against an external environment.

FIG. 2 illustrates a COC connection mode between semiconductor chips. The configuration of a semiconductor device 300 illustrated in FIG. 2 is the same as that of the semiconductor device 100, except that two semiconductor chips 1 are flip chip connected to each other through the wires or bumps 15 and the solders 30.

In FIG. 1 and FIG. 2, the connection portions such as the wires or bumps 15 may be metal films (for example, gold plating) called pads, and may be post electrodes (for example, copper pillars).

The semiconductor chip main body 10 is not particularly limited, and various semiconductors such as an element semiconductor configured from one identical element such as silicon and germanium and a compound semiconductor including gallium arsenic and indium phosphorus can be used.

The substrate 2 is not particularly limited as long as it is a wiring circuit substrate, and a circuit substrate having wires (wiring pattern) formed on the surface of an insulating substrate including glass epoxy, polyimide, polyester, ceramic, epoxy, bismaleimide triazine, or the like as a main component by removing unnecessary portions of a metal layer by etching, a circuit substrate having wires (wiring pattern) formed on the surface of the insulating substrate by metal plating or the like, a circuit substrate having wires (wiring pattern) formed by printing a conductive substance on the surface of the insulating substrate, and the like can be used.

As materials for the connection portions such as the wires or bumps 15 and 16 and the solders 30, gold, silver, copper, solder (the main component thereof is, for example, tin-silver, tin-lead, tin-bismuth, tin-copper, or tin-silver-copper), tin, nickel, and the like are used as a main component, and the connection portions may be configured by only single component and may be configured by a plurality of components. The connection portion may have a structure in which these metals are laminated. Among the metallic materials, copper and solder are relatively inexpensive, which is preferable. From the viewpoint of improving connection reliability and suppressing warpage, the connection portion may contain solder.

As materials for the pads, gold, silver, copper, solder (the main component thereof is, for example, tin-silver, tin-lead, tin-bismuth, tin-copper, or tin-silver-copper), tin, nickel, and the like are used as a main component, and the connection portions may be configured by only single component and may be configured by a plurality of components. The pad may have a structure in which these metals are laminated. From the viewpoint of connection reliability, the pad may contain gold or solder.

A metal layer containing gold, silver, copper, solder (the main component thereof is, for example, tin-silver, tin-lead, tin-bismuth, or tin-copper), tin, nickel, or the like as a main component may be formed on the surfaces of the wires or bumps 15 and 16 (wiring pattern). This metal layer may be configured by only single component and may be configured by a plurality of components. The metal layer may have a structure in which a plurality of metal layers are laminated. The metal layer may contain copper or solder that is relatively inexpensive. From the viewpoint of improving connection reliability and suppressing warpage, the metal layer may contain solder.

The semiconductor devices (package) as illustrated in FIG. 1 or FIG. 2 may be laminated and electrically connected by gold, silver, copper, solder (the main component thereof is, for example, tin-silver, tin-lead, tin-bismuth, tin-copper, tin-silver-copper), tin, nickel, or the like. The metal to be used for connection may be copper or solder that is relatively inexpensive. For example, as seen in the TSV technique, the adhesive layer may be interposed between the semiconductor chips, the semiconductor chips may be flip chip connected or laminated, holes penetrating through the semiconductor chip may be formed, and electrodes on the patterned surface may be connected.

FIG. 3 is a cross-sectional view illustrating another embodiment of the semiconductor device (an embodiment of a semiconductor chip laminate type (TSV)). In a semiconductor device 500 illustrated in FIG. 3, the wires or bumps 15 formed on an interposer main body 50 as a substrate are connected to the solders 30 of the semiconductor chip 1 to flip chip connect the semiconductor chip 1 and an interposer 5 to each other. The adhesive layer 40 is interposed between the semiconductor chip 1 and the interposer 5. The semiconductor chips 1 are repeatedly laminated on the surface of the semiconductor chip 1 on a side opposite to the interposer 5 with wires or bumps 15, the solders 30, and the adhesive layer 40 interposed therebetween. The wires or bumps 15 on the patterned surface on the front and rear sides of the semiconductor chip 1 are connected to each other through penetrating electrodes 34 provided inside of holes penetrating through the semiconductor chip main body 10. As the material for the penetrating electrode 34, copper, aluminum, or the like can be used.

Such a TSV technique enables acquisition of signals from the rear surface of the semiconductor chip, which is usually not used. Further, the penetrating electrode 34 is vertically passed through the semiconductor chip 1 to reduce the distance between the semiconductor chips 1 facing each other and the distance between the semiconductor chip 1 and the interposer 5, so that flexible connection can be attained. The adhesive layer can be applied as a sealing material between the semiconductor chips 1 facing each other and between the semiconductor chip 1 and the interposer 5 in such a TSV technique.

<Method for Manufacturing Semiconductor Device>

An embodiment of the method for manufacturing a semiconductor device includes a lamination step of laminating a first member having a connection portion and a second member having a connection portion with an adhesive for a semiconductor interposed therebetween so that the connection portion of the first member and the connection portion of the second member are disposed to face each other, and a sealing step of curing the adhesive for a semiconductor by applying heat under a pressurized atmosphere to seal at least a part of the connection portion with the cured adhesive for a semiconductor. Here, the first member is, for example, a wiring circuit substrate, a semiconductor chip, or a semiconductor wafer, and the second member is a semiconductor chip. Furthermore, the manufacturing method of the present embodiment may include, between the lamination step and the sealing step, a bonding step of forming metal bonding between the respective connection portions by press-bonding the first member and the second member of the laminate obtained in the lamination step while heating to a temperature equal to or higher than a melting point of at least one connection portion among the respective connection portions.

In a case where the first member is a semiconductor chip, the lamination step includes, for example, a step of disposing a plurality of semiconductor chips on a stage, and a temporarily fixing step of sequentially disposing another semiconductor chip on each of the plurality of semiconductor chips disposed on the stage with the adhesive for a semiconductor interposed therebetween while the stage is heated to obtain a plurality of laminates (temporarily fixed bodies) in which the semiconductor chip, the adhesive for a semiconductor, and the other semiconductor chip are laminated in this order.

In a case where the first member is a wiring circuit substrate or a semiconductor wafer, the lamination step includes, for example, a step of disposing a wiring circuit substrate or a semiconductor wafer on a stage; and a temporarily fixing step of sequentially disposing a plurality of semiconductor chips on the wiring circuit substrate or the semiconductor wafer disposed on the stage with the adhesive for a semiconductor interposed therebetween while the stage is heated to obtain a laminate (temporarily fixed body) in which the wiring circuit substrate, the adhesive for a semiconductor, and the plurality of semiconductor chips are laminated in this order or a laminate (temporarily fixed body) in which the semiconductor wafer, the adhesive for a semiconductor, and the plurality of semiconductor chips are laminated in this order.

In the temporarily fixing step, for example, first, the adhesive for a semiconductor is disposed in the first member or on the second member (for example, a film-shaped adhesive for a semiconductor is pasted). Next, each of the semiconductor chips individually divided on a dicing tape is picked up, adsorbed to a press-bonding tool (press-bonding head) of a press-bonding machine, and temporarily fixed to a wiring circuit substrate, another semiconductor chip, or a semiconductor wafer.

The method of disposing the adhesive for a semiconductor is not particularly limited, and for example, in a case where the adhesive for a semiconductor has a film shape, a method such as heat press, roll lamination, or vacuum lamination may be employed. The area and thickness of the adhesive for a semiconductor to be disposed are appropriately set depending on the sizes of the first member and the second member, the height of the connection portion (bump), and the like. The adhesive for a semiconductor may be disposed on the semiconductor chip, and the semiconductor wafer on which the adhesive for a semiconductor is disposed is diced and then individually divided into semiconductor chips.

In the temporarily fixing step, it is necessary to perform alignment to electrically connect the connection portions to each other. Therefore, generally, a press-bonding machine such as a flip chip bonder is used.

When the semiconductor chip is picked up by the press-bonding tool for temporary fixing, the press-bonding tool is preferably set to a low temperature so that heat is not transferred to the adhesive for a semiconductor or the like on the semiconductor chip. On the other hand, during press-bonding (temporary press-bonding), the semiconductor chip is preferably heated to a high temperature so that the fluidity of the adhesive for a semiconductor can be increased to efficiently eliminate trapped voids. However, heating is preferably to a temperature lower than the initiation temperature of the curing reaction of the adhesive for a semiconductor. In order to shorten the cooling time, a difference in temperature between the press-bonding tool during picking-up the semiconductor chip and the press-bonding tool during temporary fixing is preferably smaller. This temperature difference is preferably 100° C. or lower, more preferably 60° C. or lower, and substantially further preferably 0° C. When the temperature difference is 100° C. or higher, it takes a time to cool the press-bonding tool, and thus productivity tends to be deteriorated. The initiation temperature of the curing reaction of the adhesive for a semiconductor refers to an onset temperature as measured using DSC (manufactured by PerkinElmer Inc., DSC-Pyirs 1) under the conditions including a sample amount of 10 mg, a temperature increase rate of 10° C./min, and air or nitrogen atmosphere.

A load applied for temporary fixing is appropriately set in consideration of controlling of the number of connection portions (bumps), absorption of variations in height of connection portions (bumps), the deformation amount of connection portions (bumps), and the like. In the temporarily fixing step, after press-bonding (temporary press-bonding), connection portions facing each other are preferably in contact with each other. When the connection portions are in contact with each other after press-bonding, there is a tendency that the metal bonding of the connection portions in high-temperature press-bonding in the bonding step is likely to be formed, and biting of the adhesive for a semiconductor is reduced. The load is preferably larger for eliminating voids and contacting the connection portions, and the load is, for example, preferably 0.0001 to 0.2 N, more preferably 0.0005 to 0.15 N, and even more preferably 0.001 to 0.1 N, per one connection portion (bump).

The press-bonding time in the temporarily fixing step is preferably shorter from the viewpoint of improving productivity, and may be, for example, 5 seconds or shorter, 3 seconds or shorter, or 2 seconds or shorter.

The heating temperature of the stage is a temperature lower than the melting point of the connection portion of the first member and the melting point of the connection portion of the second member, and may be usually 60 to 150° C. or 70 to 100° C. By heating at such a temperature, voids trapped in the adhesive for a semiconductor can be efficiently eliminated.

The temperature of the press-bonding tool during temporary fixing is preferably set such that a temperature difference between the temperature of the press-bonding tool during temporary fixing and the temperature of the press-bonding tool during picking up the semiconductor chips is small as described above, and may be, for example, 80 to 350° C. or 100 to 170° C.

In the bonding step, metal bonding is formed between the respective connection portions by press-bonding the first member and the second member of the laminate (temporarily fixed body) obtained in the temporarily fixing step while heating to a temperature equal to or higher than a melting point of at least one connection portion among the respective connection portions (bumps). In the bonding step, a press-bonding machine such as a flip chip bonder is used.

In the bonding step, the temperature of the press-bonding tool (press-bonding head) of the press-bonding machine is regarded as a temperature equal to or higher than at least one melting point of the melting point of the connection portion of the first member and the melting point of the connection portion of the second member. The temperature of the press-bonding tool may be 180° C. or higher, 220° C. or higher, or 250° C. or higher, from the viewpoint of sufficiently forming the metal bonding between the respective connection portions. On the other hand, from the viewpoint of suppressing generation of lots of voids due to foaming and expansion of a volatile component contained in the adhesive for a semiconductor caused by rapidly applying high-temperature heat to the adhesive for a semiconductor, the temperature of the press-bonding tool may be 350° C. or lower, 320° C. or lower, or 300° C. or lower.

A load applied for press-bonding is appropriately set in consideration of controlling of the number of connection portions (bumps), absorption of variations in height of connection portions (bumps), the deformation amount of connection portions (bumps), and the like. The load is preferably larger from the viewpoint of eliminating voids and efficiently performing the metal bonding of the connection portions, and the load is, for example, preferably 0.0001 to 0.2 N, more preferably 0.0005 to 0.15 N, and even more preferably 0.001 to 0.1 N, per one connection portion (bump).

The press-bonding time in the bonding step may be, for example, 10 seconds or shorter, 5 seconds or shorter, or 4 seconds or shorter, from the viewpoint of improving productivity and suppressing progressing of curing of the adhesive for a semiconductor. On the other hand, from the viewpoint of sufficiently forming the metal bonding between the respective connection portions, the press-bonding time may be 1 second or longer, 2 seconds or longer, or 3 seconds or longer.

The heating temperature of the stage may be usually 60 to 150° C. or 70 to 100° C. By heating at such a temperature, voids trapped in the adhesive for a semiconductor can be efficiently eliminated.

In a case where the lamination step includes the temporarily fixing step and the bonding step described above, in the sealing step subsequent to the bonding step, the adhesives for a semiconductor of a plurality of laminates or a laminate (high-temperature press-bonded laminate) including a plurality of semiconductor chips may be collectively cured, and a plurality of connection portions may be sealed collectively. Through the sealing step, usually, a gap between the connection portions is filled with the adhesive for a semiconductor. Furthermore, the metal bonding between the connection portions facing each other becomes stronger. The sealing step is performed using an apparatus capable of heating and pressurizing. Examples of the apparatus include a pressurizing reflow furnace and a pressure oven.

The heating temperature (connection temperature) in the sealing step is preferably a temperature lower than the melting points of connection portions facing each other (for example, bump-bump, bump-pad, or bump-wire) and a temperature at which the adhesive for a semiconductor can be cured. The heating temperature may be, for example, 150 to 450° C. or 170 to 200° C.

In the sealing step, when pressurizing is performed using a press-bonding machine, heat of the press-bonding machine is difficult to transfer to the adhesive for a semiconductor (fillet) protruding on the side surface of the connection portion, and thus a heating treatment is further necessary for sufficiently conducting the curing of the adhesive for a semiconductor after press-bonding (main press-bonding) in many cases. Therefore, the pressurizing in the sealing step is preferably performed at an atmospheric pressure inside a pressurizing reflow furnace, a pressure oven, or the like instead of a press-bonding machine. In the case of pressurizing with an atmospheric pressure, heat can be applied to the whole adhesive, the heating treatment after press-bonding (main press-bonding) can be shortened or omitted, and thus productivity is improved. Furthermore, in the case of pressurizing with an atmospheric pressure, the main press-bonding of a plurality of laminates (high-temperature press-bonded laminates) or a laminate (high-temperature press-bonded laminate) including a plurality of semiconductor chips is easy to be performed collectively. Further, not direct pressurizing using a press-bonding machine but pressurizing with an atmospheric pressure is preferable from the viewpoint of suppressing fillet. Fillet suppression is important with respect to tendencies of a decrease in size and an increase in density of a semiconductor device.

The atmosphere under which press-bonding is performed in the sealing step is not particularly limited, but an atmosphere containing air, nitrogen, formic acid, or the like is preferable.

The pressure of press-bonding in the sealing step is appropriately set depending on the size, the number, and the like of members to be connected. The pressure may be, for example, more than an atmospheric pressure and 1 MPa or less. A larger pressure is preferable from the viewpoint of suppressing voids and improving connectivity, and a smaller pressure is preferable from the viewpoint of suppressing fillet. Therefore, the gauge pressure of the apparatus during pressurizing the laminate is more preferably 0.05 to 1.0 MPa.

The press-bonding time may be 0.1 to 3 hours, 0.2 to 2 hours, or 0.25 to 1 hour, from the viewpoint of sufficiently eliminating voids and sufficiently curing the adhesive for a semiconductor.

In a case where a plurality of semiconductor chips are laminated in a stereoscopic manner as shown in a semiconductor device having a TSV structure, a semiconductor device may be obtained by stacking the semiconductor chips one by one in a state of being temporarily fixed and high-temperature press-bonded, and then collectively heating and pressurizing the plurality of semiconductor chips laminated.

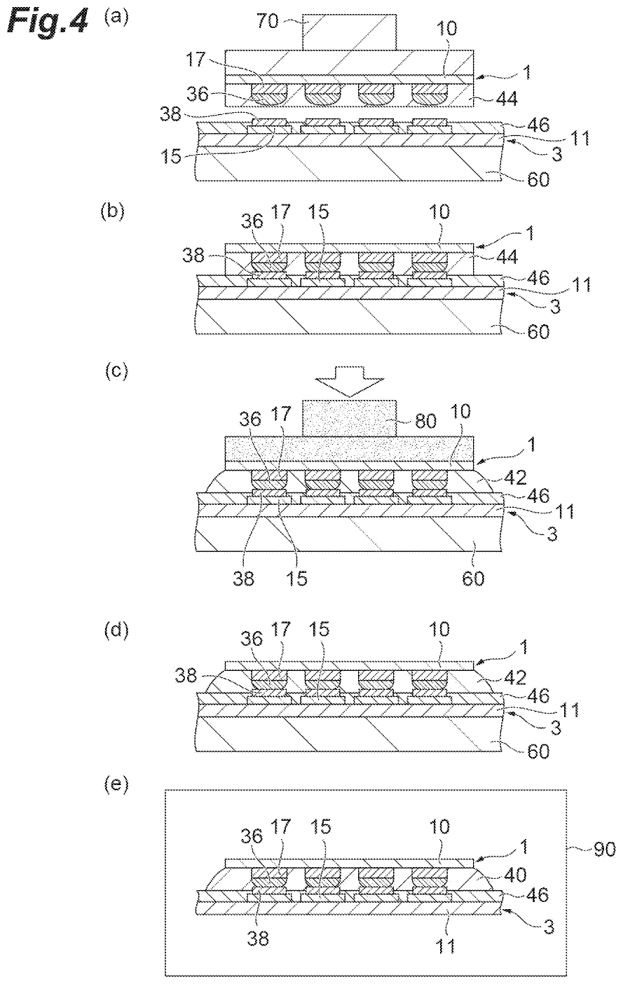

FIG. 4 is a schematic cross-sectional view illustrating an embodiment of a method for manufacturing a semiconductor device. Hereinafter, each step will be described with reference to FIG. 4. Note that, in FIG. 4, the first member is a semiconductor wafer and the second member is a semiconductor chip.

The lamination step includes, as illustrated in FIG. 4(a), a step of disposing a semiconductor wafer 3 on a stage 60, and a temporarily fixing step of sequentially disposing a plurality of semiconductor chips 1 with an adhesive 44 for a semiconductor interposed therebetween to obtain a laminate (temporarily fixed body) in which the semiconductor wafer 3, the adhesive 44 for a semiconductor, and the plurality of semiconductor chips 1 are laminated laminated in this order. The temporarily fixing step is performed using a press-bonding machine including a press-bonding tool 70. The respective conditions of the lamination step is as described above.

Here, the semiconductor wafer 3 has a semiconductor wafer main body 11, wires or bumps 15 disposed on the surface of the semiconductor wafer main body 11 on the semiconductor chip 1 side, and bumps 38 as connection portions disposed on the wires or bumps 15. Furthermore, the semiconductor wafer 3 includes a passivation film 46 for the purpose of protection of the surface of the semiconductor wafer. Examples of the constituent material for the passivation film include a polyimide resin, silicon nitride (SiN), and silicon oxide (SiO₂). Note that, the semiconductor wafer 3 may not include the passivation film 46.

The semiconductor chip 1 has the semiconductor chip main body 10, bumps or copper pillars 17 disposed on the surface of the semiconductor chip main body 10 on the semiconductor wafer 3 side, and solders 36 as connection portions disposed on the bumps or copper pillars 17. Note that, in a case where a plurality of semiconductor chips 1 are multi-staged as illustrated in FIG. 3, the penetrating electrode 34 may be provided inside the semiconductor chips 1 to be laminated.

In the present embodiment, the adhesive 44 for a semiconductor is disposed on the surface of the semiconductor chip 1 during temporary fixing. As the adhesive 44 for a semiconductor, the adhesive for a semiconductor of the present embodiment is used.

In a case where the number of the semiconductor chips 1 mounted on the semiconductor wafer 3 is large in the temporarily fixing step, as illustrated in FIG. 4(b), thermal history by the stage 60 is continuously applied to the semiconductor chip 1 initially mounted and the adhesive 44 for a semiconductor until the mounting of the final semiconductor chip 1 is completed. The time until all of the semiconductor chips 1 are mounted (time at which thermal history is continuously applied to the semiconductor chip initially mounted) varies depending on the number of the semiconductor chips 1 mounted, but is, for example, 1 to 3 hours.

In the bonding step, as illustrated in FIG. 4(c), metal bonding is formed between the solders 36 and the bumps 38 by press-bonding the semiconductor wafer 3 and the semiconductor chip 1 of the laminate (temporarily fixed body) obtained in the temporarily fixing step while heating to a temperature equal to or higher than a melting point of at least one connection portion among the respective connection portions (the solders 36 or the bumps 38). The bonding step is performed using a press-bonding machine including a press-bonding tool 80. The respective conditions of the bonding step is as described above. Furthermore, the adhesive 44 for a semiconductor may be slightly cured (semi-cured) by heating in this bonding step to the extent that fluidity thereof is still maintained in the sealing step described below. However, since the heating time in the bonding step is short, the adhesive 44 for a semiconductor is not completely cured. Through the bonding step, the adhesive 44 for a semiconductor becomes a semi-cured adhesive 42 for a semiconductor.

In a case where the number of the semiconductor chips 1 press-bonded onto the semiconductor wafer 3 is large, even in the bonding step, as illustrated in FIG. 4(d), thermal history by the stage 60 is continuously applied to the semiconductor chip 1 initially press-bonded and the semi-cured adhesive 42 for a semiconductor until the mounting of the final semiconductor chip 1 is completed. The time until all of the semiconductor chips 1 are press-bonded (time at which thermal history is continuously applied to the semiconductor chip initially mounted) varies depending on the number of the semiconductor chips 1 press-bonded, but is, for example, 1 to 3 hours.

In the sealing step, as illustrated in FIG. 4(e), the semi-cured adhesive 42 for a semiconductor is collectively cured by heating and pressurizing the laminate (high-temperature press-bonded laminate) obtained in the bonding step in a pressure oven 90 to form the adhesive layer 40 and thus plurality of connection portions are sealed collectively. The respective conditions of the sealing step is as described above.

By using the adhesive 44 for a semiconductor of the present embodiment in the above-described process, the plurality of semiconductor chips 1 can be temporarily fixed while sufficient fluidity of the adhesive 44 for a semiconductor is maintained, the amount of voids can be suppressed also during high-temperature press-bonding in the bonding step, and a reduction in generation of voids during collective curing in the sealing step and elimination of voids generated in the step before the sealing step can be achieved. Furthermore, even in a case where long-time thermal history is applied to the adhesive for a semiconductor in the temporarily fixing step and the bonding step, generation of voids can be reduced.

### EXAMPLES

Hereinafter, the present disclosure will be more specifically described by means of Examples; however, the present disclosure is not limited to the following Examples.

The compounds used in Examples and Comparative Examples are as follows.

### Component (a): Thermoplastic Resin

Polyurethane (manufactured by DIC Covestro Polymer Ltd., trade name “T-8175N”, Tg: −23° C., Mw: 120000)
Phenoxy resin (manufactured by Nippon Steel & Sumikin Chemical Co., Ltd., trade name “ZX1356-2”, Tg: about 71° C., Mw: about 63000)
Phenoxy resin (manufactured by Nippon Steel & Sumikin Chemical Co., Ltd., trade name “FX293”, Tg: about 160° C., Mw: about 40000)

Component (b): Thermosetting Resin
Triphenolmethane skeleton-containing polyfunctional solid epoxy (manufactured by Mitsubishi Chemical Corporation, trade name “EP1032H60”)
Bisphenol F type liquid epoxy (manufactured by Mitsubishi Chemical Corporation, trade name “YL983U”)

Component (c): Curing Agent
2,4-Diamino-6-[2′-methylimidazolyl-(1′)]ethyl-s-triazine isocyanuric acid adduct (manufactured by SHIKOKU CHEMICALS CORPORATION, trade name “2MAOK-PW”, Mw: 384)
2-Phenyl-4,5-dihydroxymethylimidazole ((manufactured by SHIKOKU CHEMICALS CORPORATION, trade name “2PHZ-PW”, Mw: 204)

Component (d): Flux Compound
Diphenolic acid (manufactured by Tokyo Chemical Industry Co., Ltd., melting point: 177° C., Mw: 286)
Glutaric acid (manufactured by FUJIFILM Wako Pure Chemical Corporation, melting point: 98° C., Mw: 132)

(e) Filler
Silica filler (manufactured by ADMATECHS COMPANY LIMITED, trade name “SE2030”, average particle diameter: 0.5 μm)
Expoxysilane-surface-treated silica filler (manufactured by ADMATECHS COMPANY LIMITED, trade name “SE2030-SEJ”, average particle diameter: 0.5 μm)
Methacrylic-surface-treated silica filler (manufactured by ADMATECHS COMPANY LIMITED, trade name “YA050C-SM1”, average particle diameter: about 0.05 μm)

The weight average molecular weight (Mw) of the component (a) is determined by a GPC method. The details of the GPC method are as shown below.
Device name: HPLC-8020 (product name, manufactured by Tosoh Corporation)
Column: 2 pieces of GMHXL+1 piece of G-2000XL
Detector: RI detector
Column temperature: 35° C.
Flow rate: 1 mL/min
Standard substance: polystyrene

<Production of Film-Shaped Adhesive for Semiconductor>

A thermoplastic resin, a thermosetting resin, a curing agent, a flux compound, and a filler were added to an organic solvent (cyclohexanone) in blending amounts (unit: parts by mass) shown in Table 1 so that the NV value ([the mass of the coating material content after drying]/[the mass of the coating material content before drying]×100) reached 50%. Thereafter, Φ1.0 mm zirconia beads and Φ2.0 mm zirconia beads were added into the same container at the mass equal to the blending amount of solid contents (the thermoplastic resin, the thermosetting resin, the curing agent, the flux compound, and the filler) and stirred for 30 minutes with a ball mill (Fritsch Japan Co., Ltd., planetary pulverizing mill P-7). After stirring, the zirconia beads were removed by filtration to prepare a coating varnish.

The obtained coating varnish was applied onto a base material film (manufactured by Teijin DuPont films Japan Ltd., trade name “Purex A55”) with a compact precision coating apparatus (manufactured by Yasui Seiki Company, Ltd.) and dried in a clean oven (manufactured by ESPEC CORP.) (100° C./10 min) to obtain a film-shaped adhesive (film-shaped adhesive for a semiconductor) having a film thickness of 20 μm.

Hereinafter, an evaluation method of the film-shaped adhesives obtained in Examples and Comparative Examples is shown. The evaluation results are shown in Table 1.

<Dsc Measurement>

10 mg of the obtained film-shaped adhesive was weighed in an aluminum pan (manufactured by Epolead Service Inc.), the aluminum pan was covered with an aluminum lid, and an evaluation sample was hermetically sealed in a sample pan by using a crimper. The measurement was performed using a differential scanning calorimeter (Thermo plus DSC8235E, manufactured by Rigaku Corporation) under a nitrogen atmosphere at a temperature increase rate of 10° C./min and in a measurement temperature range of 30 to 300° C. As an analytical means for the exothermic calorific value, an analysis method of a partial area was used, and an analysis instruction in a temperature range of 60° C. to 280° C. of each DSC curve was made to perform baseline designation of an analysis temperature range and integration of a peak area, thereby calculating the total exothermic calorific value (unit: J/g). Subsequently, an instruction to set 155° C. as a divided temperature was made to integrate each partial area at 60 to 155° C. and 155 to 280° C., thereby calculating each exothermic calorific value (unit: J/g). On the other hand, as an analytical means of the onset temperature, an analysis method of the total area (JIS method) was used, and an analysis instruction in a temperature range of 60° C. to 280° C. was made to calculate an intersecting point between the baseline of a peak in each DSC curve and the maximum incline point, thereby determining the onset temperature (unit: ° C.).

<High-Temperature Standing Stability Evaluation>

The DSC curve obtained above was analyzed to calculate the exothermic calorific value (unit: J/g) at 60 to 280° C. This value was regarded as an initial exothermic calorific value.

The film-shaped adhesive (initial sample) each obtained in Examples and Comparative Examples was put in an oven set at 100° C. and subjected to a heating treatment for 1 hour, and then the sample was taken out to obtain a sample A for evaluation after being heat-treated at 100° C.

The film-shaped adhesive (initial sample) each obtained in Examples and Comparative Examples was put in an oven set at 80° C. and subjected to a heating treatment for 6 hours, and then the sample was taken out to obtain a sample B for evaluation after being heat-treated at 80° C.

The exothermic calorific value (unit: J/g) at 60 to 280° C. was calculated according to the same procedure as that before heating by using the sample A for evaluation and the sample B for evaluation. This value was regarded as an exothermic calorific value after the heat treatment.

The reaction rate was calculated by the following equation using two exothermic calorific values thus obtained (the exothermic calorific value of the initial sample and the exothermic calorific value of the sample A for evaluation or the exothermic calorific value of the initial sample and the exothermic calorific value of the sample B for evaluation).

Reaction rate (%)=(Initial exothermic calorific value−Exothermic calorific value after heat treatment)/Initial exothermic calorific value×100

A case where the reaction rate is less than 10% was determined as “A”, a case where the reaction rate is 10% or more and less than 20% was determined as “B”, and a case where the reaction rate is 20% or more was determined as “C”.

<Viscosity Measurement>

Each of the film-shaped adhesives (initial samples) obtained in Examples and Comparative Examples was used, and a plurality of the film-shaped adhesives were overlapped using a tabletop laminator (product name: Hotdog GK-13DX, manufactured by LAMI CORPORATION INC.) and laminated to have a thickness of 400 μm, thereby producing a sample for viscosity measurement. As for lamination conditions, lamination was performed under an apparatus setting temperature of 50° C. and an apparatus transportation velocity level of 9.

The laminated samples for viscosity measurement were punched using a 10 mm-square punch, and the melt temperature at 80° C. (80° C. viscosity), the melt temperature at 130° C. (130° C. viscosity), the minimum melt viscosity, and the temperature (melt temperature) at which the minimum melt viscosity was shown were measured using a rotary rheometer (manufactured by TA Instruments, trade name:
ARES-G2).
[Measurement conditions]
Measurement tool size: 9 mmϕ
Sample thickness: 400 μm
Temperature increase rate: 10° C./min
Frequency: 10 Hz
Temperature range: 30 to 180° C.

<Void Evaluation>

(Manufacturing of Semiconductor Device)

The film-shaped adhesives (initial samples) obtained in Examples and Comparative Examples were laminated using a tabletop laminator (product name: Hotdog GK-13DX, manufactured by LAMI CORPORATION INC.) to have a film thickness of 40 μm, and then cut into a size of 7.5 mm×7.5 mm, and the cut film-shaped adhesives were pasted at 80° C. onto a plurality of solder bump-attached semiconductor chips (chip size: 7.3 mm×7.3 mm, thickness 0.1 mm, bump (connection portion) height: about 45 μm (total of copper pillar and solder), the number of bumps: 1048 pins, pitch 80 μm, product name: WALTS-TEG CC80, manufactured by WALTS CO., LTD.). Chips for a semiconductor attached with the film-shaped adhesive were sequentially press-bonded and temporarily fixed to other semiconductor chips (chip size: 10 mm×10 mm, thickness 0.1 mm, the number of bumps: 1048 pins, pitch 80 μm, product name: WALTS-TEG IP80, manufactured by WALTS CO., LTD.) by heating and pressurizing with a flip chip bonder (FCB3, manufactured by Panasonic Corporation). The stage temperature during temporary fixing was set to 70° C., and the press-bonding conditions were set to a tool temperature of 130° C., a load of 25 N (0.024 N per one bump), and a time of 3 seconds, thereby producing a laminate (temporarily fixed body) after temporary press-bonding.

The laminate (temporarily fixed body) after the temporary press-bonding was high-temperature press-bonded with a flip chip bonder (FCB3, manufactured by Panasonic Corporation). The stage temperature during high-temperature press-bonding was set to 70° C., and the press-bonding conditions were set to a tool temperature of 260° C., a load of 35 N (0.033 N per one bump), and a time of 3 seconds, thereby obtaining a sample C for evaluation (high-temperature press-bonded laminate) in which the connection portions were metal bonded.

The sample C for evaluation (high-temperature press-bonded laminate) that is the laminate after high-temperature press-bonding was heated inside a pressure oven to 190° C. at a temperature increase rate of 20° C./min, and heated and pressurized for 1 hour under the conditions of 190° C. and 0.8 MPa, thereby obtaining a sample D for evaluation (pressurized laminate).

On the other hand, the sample C for evaluation (high-temperature press-bonded laminate) that is the laminate after high-temperature press-bonding was subjected to a heat treatment for 6 hours inside an oven set at 80° C., taken out once, and then heated to 190° C. at a temperature increase rate of 20° C./min in a pressure oven, and heated and pressurized for 1 hour under the conditions of 190° C. and 0.8 MPa, thereby obtaining a sample E for evaluation (thermal history pressurized laminate).

(Analysis and Evaluation)

An image of the inside of the sample for evaluation was taken with an ultrasonic image diagnostic apparatus (Insight-300, manufactured by Insight k.k.) using the sample C for evaluation, the sample D for evaluation, and the sample E for evaluation described above. From the obtained image, an image of the adhesive layer between chips was imported by a scanner (GT-9300UF, manufactured by Seiko Epson Corporation). The imported image was subjected to color tone correction and black and white conversion with an image processing software (Adobe Photoshop (trade name)) to distinguish void portions, and the proportion of the void portions was calculated based on a histogram. The area of the entire adhesive layer including void portions was regarded as 100 area %. A case where the area ratio of voids is less than 5% was determined as “A”, a case where the area ratio of voids is 5% or more and less than 20% was determined as “B”, and a case where the area ratio of voids is 20% or more was determined as “C”. The evaluation results are shown in Table 1.

TABLE 1

| | | Example | | | | Comparative Example | | |
|---|---|---|---|---|---|---|---|---|
| | | 1 | 2 | 3 | 4 | 1 | 2 | 3 |
| Component (a) | T8175N | 11.7 | 11.3 | 10.6 | 11.7 | — | — | 12.9 |
| | ZX-1356-2 | — | — | — | — | 17.0 | — | — |
| | FX293 | — | — | — | — | — | 12.2 | — |
| Component (b) | EP1032H60 | 35.5 | 33.5 | 31.7 | 35.1 | 25.6 | 27.4 | 39.0 |
| | YL983U | — | — | — | — | 11.4 | 12.2 | — |
| Component (c) | 2PHZ | 1.2 | 1 | 1.1 | 1.2 | — | — | 1.3 |
| | 2MAOK | — | — | — | — | 1.1 | 2.4 | — |
| Component (d) | Diphenolic acid | 1.2 | 1.1 | 1.1 | 2.4 | — | — | 1.3 |
| | Glutaric acid | — | — | — | — | 2.3 | 2.4 | — |
| Component (e) | SE2030 | 10.1 | 10.6 | 11.1 | 9.9 | 8.5 | 8.7 | 9.1 |
| | SE2030-SEJ | 10.1 | 10.6 | 11.1 | 9.9 | 8.5 | 8.7 | 9.1 |
| | YA050C-SM1 | 30.2 | 31.8 | 33.3 | 29.8 | 25.6 | 26.0 | 27.3 |
| DSC measurement | Onset temperature (° C.) | 170 | 170 | 170 | 167 | 144 | 154 | 170 |
| (initial) | Exothermic calorific value @60-155° C. (J/g) | −12 | −10 | −10 | −11 | 22 | 21 | −14 |
| | Exothermic calorific value @155-280° C. (J/g) | 84 | 76 | 70 | 95 | 125 | 152 | 92 |
| | Exothermic calorific value @60-280° C. (J/g) | 72 | 66 | 60 | 84 | 147 | 173 | 78 |
| DSC measurement | Exothermic calorific value @60-280° C. (J/g) | 72 | 66 | 60 | 78 | 109 | 134 | 78 |
| (after 100° C./ | Reaction rate (%) | 0 | 0 | 0 | 7 | 26 | 23 | 0 |
| 1 h treatment) | High-temperature standing stability | A | A | A | A | C | C | A |
| DSC measurement | Exothermic calorific value @60-280° C. (J/g) | 72 | 66 | 50 | 80 | 130 | 148 | 78 |
| (after 80° C./ | Reaction rate (%) | 0 | 0 | 0 | 5 | 12 | 14 | 0 |
| 6 h treatment) | High-temperature standing stability | A | A | A | A | C | C | A |
| Viscosity | 80° C. viscosity (Pa · s) | 12100 | 15500 | 18600 | 10100 | 5800 | 7500 | 9000 |
| measurement | 130° C. viscosity (Pa · s) | 4100 | 5300 | 8300 | 3600 | 2300 | 3900 | 2800 |
| | Minimum melt viscosity (Pa · s) | 3100 | 4300 | 7800 | 3100 | 2200 | 3800 | 1700 |
| | Melt temperature (° C.) | 148 | 149 | 145 | 145 | 137 | 133 | 151 |
| Void evaluation | Sample C for evaluation | B | B | B | B | B | B | C |
| | Sample D for evaluation | A | A | A | A | B | B | B |
| | Sample E for evaluation | A | A | A | A | B | B | B |

### REFERENCE SIGNS LIST

1: semiconductor chip, 2: substrate, 3: semiconductor wafer, 10: semiconductor chip main body, 11: semiconductor wafer main body, 15, 16: wire or bump, 17: bump or copper pillar, 20: substrate main body, 30, 36: solder, 34: penetrating electrode, 38: bump, 40: adhesive layer, 42: semi-cured adhesive for semiconductor, 44: adhesive for semiconductor, 46: passivation film, 50: interposer main body, 60: stage, 70, 80: press-bonding tool, 90: pressure oven, 100, 300, 500: semiconductor device.

1. An adhesive for a semiconductor, the adhesive comprising: a thermoplastic resin; a thermosetting resin; a curing agent; and a flux compound having an acid group, wherein
an exothermic calorific value at 60 to 155° C. of a DSC curve obtained by differential scanning calorimetry in which the adhesive for a semiconductor is heated at a temperature increase rate of 10° C./min is 20 J/g or less, and
a minimum melt viscosity of a viscosity curve obtained by shear viscosity measurement in which the adhesive for a semiconductor is heated at a temperature increase rate of 10° C./min is 2000 Pa·s or more.

2. The adhesive for a semiconductor according to claim 1, wherein the minimum melt viscosity is 3000 Pa·s or more.

3. The adhesive for a semiconductor according to claim 1, wherein the minimum melt viscosity is 4000 Pa·s or more.

4. The adhesive for a semiconductor according to claim 1, wherein the minimum melt viscosity is 20000 Pa·s or less.

5. The adhesive for a semiconductor according to claim 1, wherein the minimum melt viscosity is 15000 Pa·s or less.

6. The adhesive for a semiconductor according to claim 1, wherein the minimum melt viscosity is 10000 Pa·s or less.

7. The adhesive for a semiconductor according to claim 1, wherein an onset temperature of the DSC curve obtained by differential scanning calorimetry in which the adhesive for a semiconductor is heated at a temperature increase rate of 10° C./min is 155° C. or higher.

8. The adhesive for a semiconductor according to claim 1, wherein a temperature at which the adhesive for a semiconductor has the minimum melt viscosity is 135° C. or higher.

9. The adhesive for a semiconductor according to claim 1, wherein a temperature at which the adhesive for a semiconductor has the minimum melt viscosity is 140° C. or higher.

10. The adhesive for a semiconductor according to claim 1, wherein a temperature at which the adhesive for a semiconductor has the minimum melt viscosity is 145° C. or higher.

11. The adhesive for a semiconductor according to claim 1, wherein a viscosity at 80° C. of the viscosity curve obtained by shear viscosity measurement in which the adhesive for a semiconductor is heated at a temperature increase rate of 10° C./min is 10000 Pa·s or more.

12. The adhesive for a semiconductor according to claim 1, wherein a weight average molecular weight of the thermoplastic resin is 10000 or more.

13. The adhesive for a semiconductor according to claim 1, wherein a content of the thermoplastic resin is 1 to 30% by mass on the basis of the total amount of solid contents of the adhesive for a semiconductor.

14. The adhesive for a semiconductor according to claim 1, wherein a content of the thermoplastic resin is 5% by mass or more on the basis of the total amount of solid contents of the adhesive for a semiconductor.

15. The adhesive for a semiconductor according to claim 1, wherein the curing agent comprises an amine-based curing agent.

16. The adhesive for a semiconductor according to claim 1, wherein the curing agent comprises an imidazole-based curing agent.

17. The adhesive for a semiconductor according to claim 1, wherein a content of the curing agent is 2.3% by mass or less on the basis of the total amount of solid contents of the adhesive for a semiconductor.

18. The adhesive for a semiconductor according to claim 1, wherein a melting point of the flux compound is 25 to 230° C.

19. The adhesive for a semiconductor according to claim 1, wherein a melting point of the flux compound is 100 to 170° C.

20. The adhesive for a semiconductor according to claim 1, wherein the thermosetting resin comprises an epoxy resin.

21. The adhesive for a semiconductor according to claim 1, wherein the thermosetting resin does not substantially comprise an epoxy resin that is a liquid at 35° C.

22. The adhesive for a semiconductor according to claim 1, wherein the adhesive for a semiconductor has a film shape.

23. The adhesive for a semiconductor according to claim 1, wherein the adhesive for a semiconductor is cured by applying heat under a pressurized atmosphere.

24. A method for manufacturing a semiconductor device in which connection portions of a semiconductor chip and a wiring circuit substrate are electrically connected to each other or a semiconductor device in which connection portions of a plurality of semiconductor chips are electrically connected to each other, the method comprising:
a sealing step of curing the adhesive for a semiconductor according to claim 1 by applying heat under a pressurized atmosphere to seal at least a part of the connection portion with the cured adhesive for a semiconductor.

25. The method for manufacturing a semiconductor device according to claim 24, further comprising, before the sealing step:
a step of disposing a plurality of semiconductor chips on a stage; and
a temporarily fixing step of sequentially disposing another semiconductor chip on each of the plurality of semiconductor chips disposed on the stage with the adhesive for a semiconductor interposed therebetween while the stage is heated to 60 to 155° C. to obtain a plurality of laminates in which the semiconductor chip, the adhesive for a semiconductor, and the other semiconductor chip are laminated in this order.

26. The method for manufacturing a semiconductor device according to claim 25, further comprising, after the temporarily fixing step and before the sealing step,
a bonding step of forming metal bonding between the respective connection portions by press-bonding the semiconductor chips and the other semiconductor chips while heating to a temperature equal to or higher than a melting point of at least one connection portion among the respective connection portions.

27. The method for manufacturing a semiconductor device according to claim 24, further comprising, before the sealing step:
a step of disposing a wiring circuit substrate or a semiconductor wafer on a stage; and
a temporarily fixing step of sequentially disposing a plurality of semiconductor chips on the wiring circuit substrate or the semiconductor wafer disposed on the stage with the adhesive for a semiconductor interposed therebetween while the stage is heated to 60 to 155° C. to obtain a laminate in which the wiring circuit substrate, the adhesive for a semiconductor, and the plurality of semiconductor chips are laminated in this order or a laminate in which the semiconductor wafer, the adhesive for a semiconductor, and the plurality of semiconductor chips are laminated in this order.

28. The method for manufacturing a semiconductor device according to claim 27, further comprising, after the temporarily fixing step and before the sealing step,
a bonding step of forming metal bonding between the respective connection portions by press-bonding the wiring circuit substrate or the semiconductor wafer and the semiconductor chips while heating to a temperature equal to or higher than a melting point of at least one connection portion among the respective connection portions.

29. A semiconductor device in which connection portions of a semiconductor chip and a wiring circuit substrate are electrically connected to each other or a semiconductor device in which connection portions of a plurality of semiconductor chips are electrically connected to each other, at least a part of the connection portion being sealed with a cured product of the adhesive for a semiconductor according to claim 1 cured by applying heat under a pressurized atmosphere.
